(19) United States
(12) Patent Application Publication
(10) Pub. No.: US 2026/0130230 A1
(43) Pub. Date: May 7, 2026

(54) SEMICONDUCTOR PACKAGE

(71) Applicant: SAMSUNG ELECTRONICS CO., LTD., Suwon-si (KR)

(72) Inventors: Hyeseon PARK, Suwon-si (KR); Yongkwan LEE, Suwon-si (KR)

(73) Assignee: SAMSUNG ELECTRONICS CO., LTD., Suwon-si (KR)

(21) Appl. No.: 19/368,588

(22) Filed: Oct. 24, 2025

(30) Foreign Application Priority Data
Nov. 1, 2024 (KR) 10-2024-0153445

(51) Int. Cl. H01L 23/544; H01L 21/56; H01L 21/78; H01L 23/00; H01L 23/31; H01L 25/065

(52) U.S. Cl. CPC H10W 46/00; H10P 54/00; H10W 74/014; H10W 74/111; H10W 90/00; H10W 46/603; H10W 72/07254; H10W 72/247; H10W 90/26; H10W 90/297; H10W 90/722; H10W 90/724

(57) ABSTRACT

A semiconductor package may include: a first double-chip structure including a first semiconductor chip, a second semiconductor chip, a first scribe lane region dividing the first semiconductor chip and the second semiconductor chip, and a first through hole in the first scribe lane region; a second double-chip structure on the first double-chip structure, the second double-chip structure including a third semiconductor chip, a fourth semiconductor chip, a second scribe lane region dividing the third semiconductor chip and the fourth semiconductor chip, and a second through hole in the second scribe lane region; first conductive connection members between the first and second double-chip structures and configured to electrically connect the first and third semiconductor chips and the second and fourth semiconductor chips; and a molding member on the first double-chip structure and the second double-chip structure and in the first through hole and the second through hole.

### CROSS-REFERENCE TO RELATED APPLICATION

This application claims priority under 35 U.S.C. § 119 to Korean Patent Application No. 10-2024-0153445, filed on Nov. 1, 2024, in the Korean Intellectual Property Office (KIPO), the contents of which are herein incorporated by reference in their entirety.

### BACKGROUND

### 1. Field

Some example embodiments of the present disclosure relate to a semiconductor package. More particularly, some example embodiments of the present disclosure relate to a semiconductor package including a double-chip structure with a pair of semiconductor chips and a molding member covering the double-chip structure.

### 2. Description of Related Art

In a molded underfill (MUF) process, the higher a chip is located among stacked chips, the faster a molding material can be filled. Additionally, in the MUF process, a peripheral region of the chip may be quickly filled with the molding material compared to a central region of the same chip. Accordingly, the central region of the lowest chip among the stacked chips may be filled with the molding material late compared to the peripheral region of the uppermost chip, so voids may occur in a portion of the molding material below the lowest chip among the stacked chips. In addition, since the peripheral region portion of the uppermost chip is filled with the molding material first, warpage may occur during the molding process, and as a result, bumps of the lowest chip may be pressed.

### SUMMARY

According to some example embodiments of the present disclosure, a semiconductor package may be provided and have a passage through which a molding material moves to prevent a void from occurring in the molding material.

According to some embodiments of the present disclosure, a semiconductor package may include: a first double-chip structure including a first semiconductor chip, a second semiconductor chip, and a first scribe lane region dividing the first semiconductor chip and the second semiconductor chip, and at least one first through hole in the first scribe lane region; a second double-chip structure on the first double-chip structure, the second double-chip structure including a third semiconductor chip on the first semiconductor chip, a fourth semiconductor chip on the second semiconductor chip, and a second scribe lane region dividing the third semiconductor chip and the fourth semiconductor chip, and at least one second through hole in the second scribe lane region; a plurality of first conductive connection members between the first double-chip structure and the second double-chip structure, the plurality of first conductive connection members configured to electrically connect the first semiconductor chip and the third semiconductor chip and configured to electrically connect the second semiconductor chip and the fourth semiconductor chip; and a molding member on the first double-chip structure and the second double-chip structure and in the at least one first through hole and the at least one second through hole.

According to some embodiments of the present disclosure, a semiconductor package may include: a substrate structure including a mounting region; a first double-chip structure on the mounting region of the substrate structure, the first double-chip structure including: a pair of first semiconductor chips arranged along a first horizontal direction; a first scribe lane region dividing the pair of first semiconductor chips; and a first penetration portion penetrating the first scribe lane region; a second double-chip structure on the first double-chip structure, the second double-chip structure including: a pair of second semiconductor chips arranged along the first horizontal direction; a second scribe lane region dividing the pair of second semiconductor chips; and a second penetration portion penetrating the second scribe lane region; at least one first conductive connection member between the substrate structure and the first double-chip structure, wherein the at least one first conductive connection member is configured to electrically connect the substrate structure and the first double-chip structure; at least one second conductive connection member between the first double-chip structure and the second double-chip structure, wherein the at least one second conductive connection member is configured to electrically connect the first double-chip structure and the second double-chip structure; and a molding member on the substrate structure, the first double-chip structure, and the second double-chip structure, wherein the molding member is in the first penetration portion and the second penetration portion.

According to some embodiments of the present disclosure, a semiconductor package may include: a substrate structure including a mounting region; a first double-chip structure on the mounting region of the substrate structure, the first double-chip structure including a first semiconductor chip, a second semiconductor chip, and a first scribe lane region dividing the first semiconductor chip and the second semiconductor chip; a second double-chip structure on the first double-chip structure, the second double-chip structure including a third semiconductor chip on the first semiconductor chip, a fourth semiconductor chip on the second semiconductor chip, and a second scribe lane region dividing the third semiconductor chip and the fourth semiconductor chip; at least one first conductive connection member between the substrate structure and the first double-chip structure, wherein a first gap is between the substrate structure and the first double-chip structure, and the at least one first conductive connection member is configured to electrically connect the substrate structure and the first double-chip structure; at least one second conductive connection member between the first double-chip structure and the second double-chip structure, wherein a second gap is between the first double-chip structure and the second double-chip structure, and the at least one second conductive connection member is configured to electrically connect the first double-chip structure and the second double-chip structure; and a molding member on the substrate structure, the first double-chip structure, and the second double-chip structure, wherein the first double-chip structure further includes at least one first through hole in the first scribe lane region, wherein the second double-chip structure further includes at least one second through hole in the second scribe lane region, and wherein the molding member is in the first gap, the second gap, the at least one first through hole, and the at least one second through hole.

According to some example embodiments of the present disclosure, a semiconductor package may include a substrate structure, a first double-chip structure and a second double-chip structure sequentially stacked on the substrate structure, and a molding member covering the first and second double-chip structures.

The first double-chip structure may include a pair of first semiconductor chips and a first scribe lane region connecting the pair of first semiconductor chips. The second double-chip structure may include a pair of second semiconductor chips and a second scribe lane region connecting the pair of second semiconductor chips.

The first double-chip structure may have a plurality of first through holes in the first scribe lane region. The second double-chip structure may have a plurality of second through holes in the second scribe lane region.

According to some example embodiments of the present disclosure, a molding material for forming the molding member may be moved toward a central portion of the first double-chip structure and a central portion of the second double-chip structure through the plurality of first through holes and the plurality of second through holes, thereby reducing a flow speed difference of the molding material between the central portion of the first double-chip structure (or the second double-chip structure) and a peripheral portion of the first double-chip structure (or the second double-chip structure). Thus, the plurality of first through holes and the plurality of second through holes may prevent voids from occurring on a lower portion of the first double-chip structure, such as a lowest chip, and may prevent bumps of the lowest chip from being pressed.

### BRIEF DESCRIPTION OF DRAWINGS

FIG. 1 is a cross-sectional view illustrating a semiconductor package in accordance with example embodiments.

FIG. 2 is a cross-sectional view illustrating the semiconductor package of FIG. 1.

FIG. 3 is a plan view illustrating the semiconductor package of FIG. 1.

FIG. 4 is a cross-sectional view illustrating a first double-chip structure of FIG. 1.

FIG. 5 is a plan view illustrating the first double-chip structure of FIG. 4.

FIG. 6 is a cross-sectional view illustrating a second double-chip structure of FIG. 1.

FIG. 7 is a plan view illustrating the second double-chip structure of FIG. 6.

FIGS. 8 to 28 are views illustrating a method of manufacturing a semiconductor package in accordance with example embodiments.

FIG. 29 is a cross-sectional view illustrating a semiconductor package in accordance with example embodiments.

FIG. 30 is a cross-sectional view illustrating the semiconductor package of FIG. 29.

FIG. 31 is a cross-sectional view illustrating a semiconductor package in accordance with example embodiments.

FIG. 32 is a cross-sectional view illustrating the semiconductor package of FIG. 31.

FIG. 33 is a cross-sectional view illustrating a semiconductor package in accordance with example embodiments.

FIG. 34 is a cross-sectional view illustrating the semiconductor package of FIG. 33.

FIG. 35 is a plan view illustrating a semiconductor package in accordance with example embodiments.

FIG. 36 is a cross-sectional view taken along a line C7-C7′ of FIG. 35.

### DETAILED DESCRIPTION

It will be understood that when an element or layer is referred to as being “on,” “connected to,” or “coupled to” another element or layer, it can be directly on, connected to, or coupled to the other element or layer or intervening elements or layers may be present. In contrast, when an element or layer is referred to as being “directly on,” “directly connected to,” or “directly coupled to” another element or layer, there are no intervening elements or layers present.

Hereinafter, non-limiting example embodiments of the present disclosure will be explained in detail with reference to the accompanying drawings.

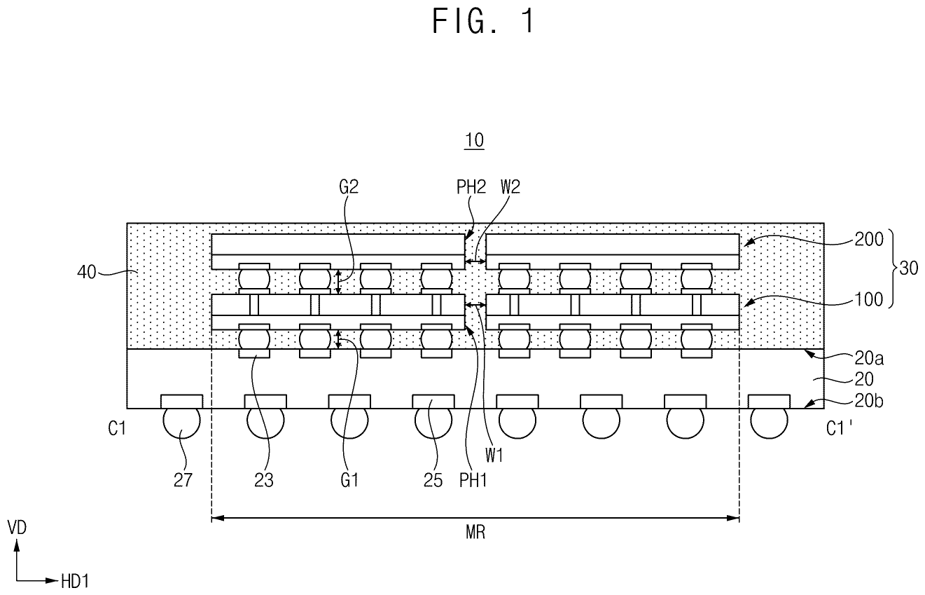

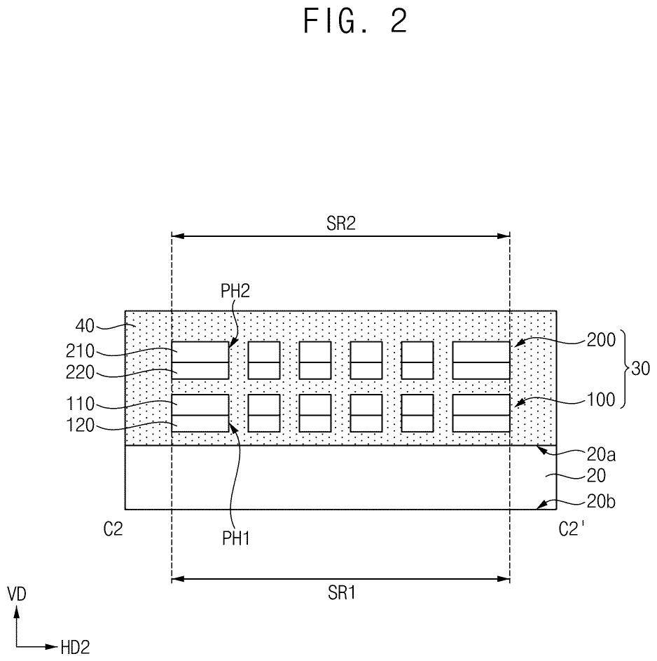

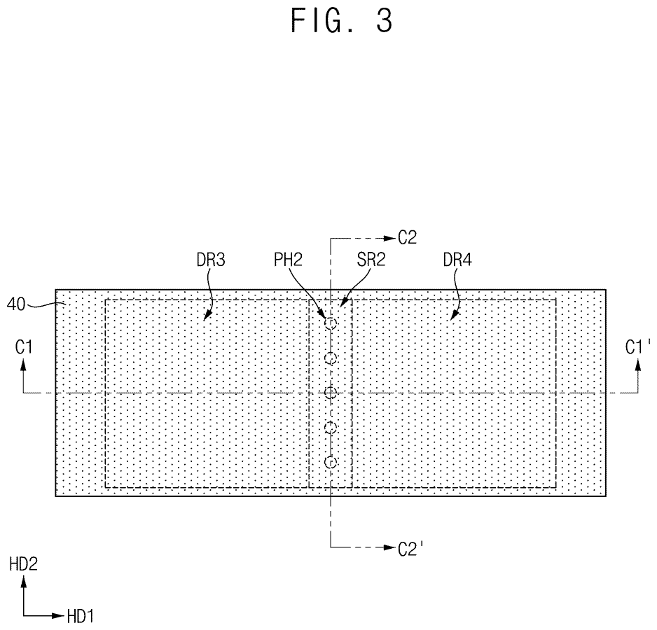

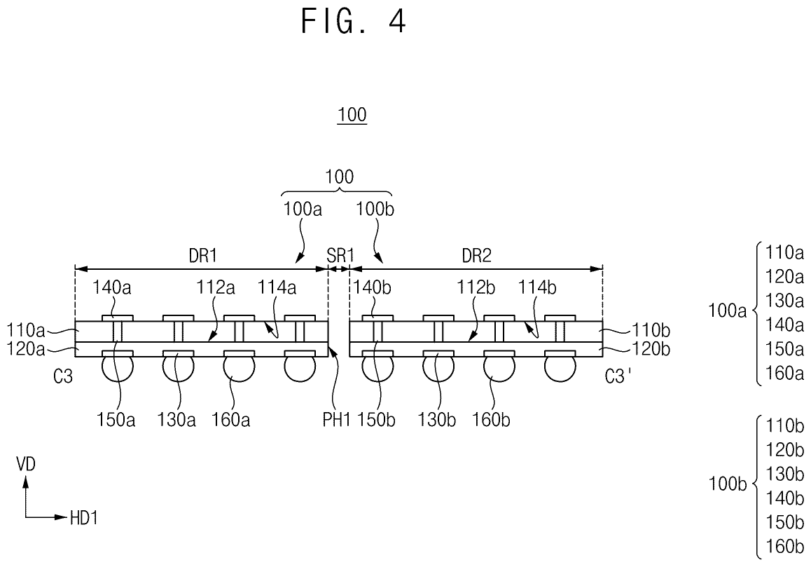

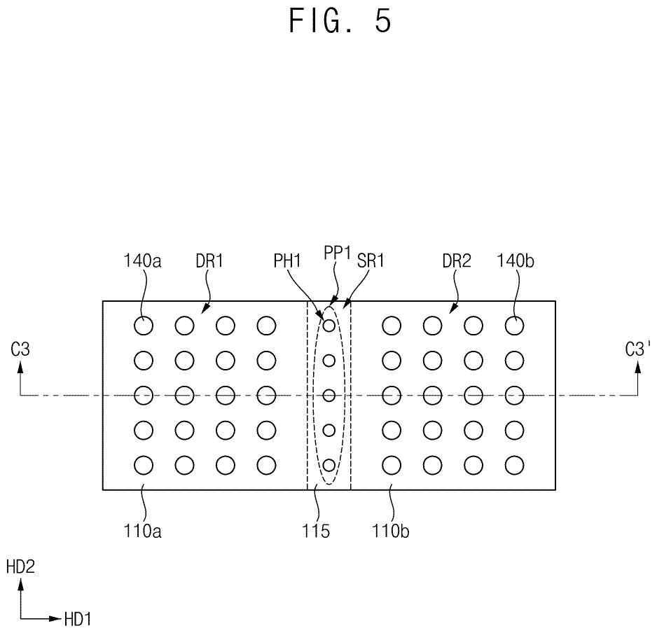

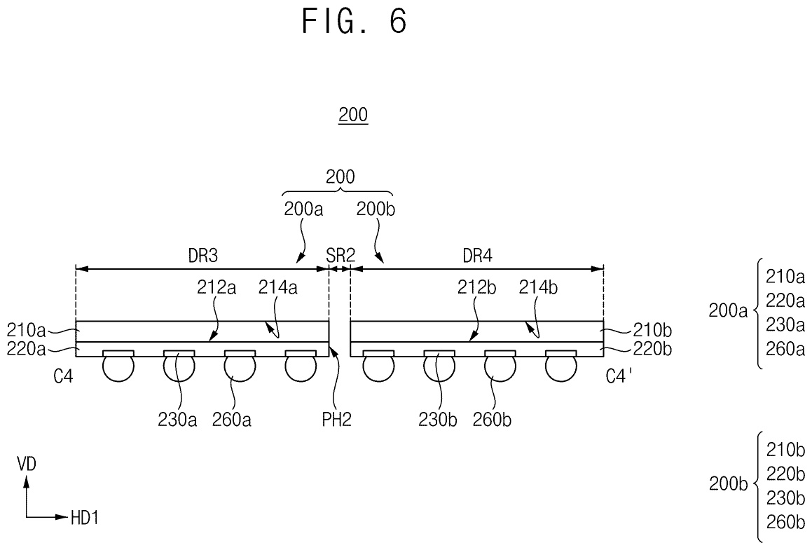

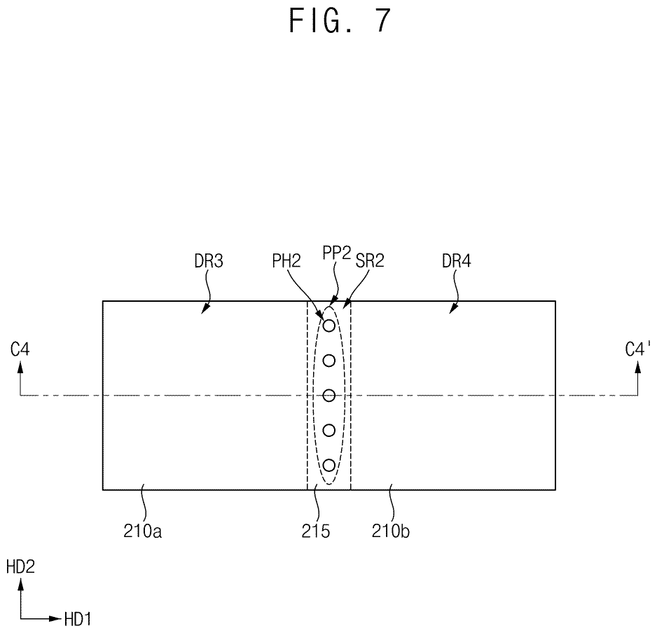

FIG. 1 is a cross-sectional view illustrating a semiconductor package in accordance with example embodiments. FIG. 2 is a cross-sectional view illustrating the semiconductor package of FIG. 1. FIG. 3 is a plan view illustrating the semiconductor package of FIG. 1. FIG. 4 is a cross-sectional view illustrating a first double-chip structure of FIG. 1. FIG. 5 is a plan view illustrating the first double-chip structure of FIG. 4. FIG. 6 is a cross-sectional view illustrating a second double-chip structure of FIG. 1. FIG. 7 is a plan view illustrating the second double-chip structure of FIG. 6. FIG. 1 is a cross-sectional view taken along a line C1-C1′ of FIG. 3. FIG. 2 is a cross-sectional view taken along a line C2-C2′ of FIG. 3. FIG. 4 is a cross-sectional view taken along a line C3-C3′ of FIG. 5. FIG. 6 is a cross-sectional view taken along a line C4-C4′ of FIG. 7.

Referring to FIGS. 1 to 7, a semiconductor package 10 may include a substrate structure 20, a plurality of double-chip structures 30 sequentially stacked on the substrate structure 20, and a molding member 40 on the substrate structure 20 to cover the plurality of double-chip structures 30.

In example embodiments, the substrate structure 20 may have a first surface 20a and a second surface 20b opposite to the first surface 20a. The substrate structure 20 may include a plurality of first substrate pads 23 provided at (e.g., in or on) the first surface 20a and a plurality of second substrate pads 25 provided at (e.g., in or on) the second surface 20b. The substrate structure 20 may further include a plurality of external connection members 27 respectively disposed on the plurality of second substrate pads 25. For example, the plurality of external connection members 27 may be configured to connect the semiconductor package 10 with an external device on which the substrate structure 20 is mounted. For example, the substrate structure 20 may include a printed circuit board (PCB), an interposer, a buffer chip, or the like. For example, when the substrate structure 20 includes a buffer chip, the semiconductor package 10 may be a high bandwidth memory (HBM) device including a plurality of double-chip structures 30 having a plurality of core chips. However, it will be appreciated that example embodiments are not limited thereto.

The substrate structure 20 may include a chip mounting region MR at a central region of the substrate structure 20. The plurality of first substrate pads 23 may be provided within the chip mounting region MR to be at least partially exposed from the first surface 20a. For example, the chip mounting region MR may be a region where the double-chip structures 30 are sequentially stacked as will be described below.

Although a few pads (e.g., first substrate pads 23) are illustrated in the figures, it will be appreciated that example embodiments are not limited thereto. Accordingly, the number, size, arrangement, shape, etc., of the pads may be varied. Additionally, the substrate structure 20 may have internal wirings that are electrically connected the pads.

In example embodiments, the plurality of double-chip structures 30 may include a first double-chip structure 100 and a second double-chip structure 200 sequentially mounted on the chip mounting region MR of the substrate structure 20. For example, each of the first double-chip structure 100 and the second double-chip structure 200 may be a semiconductor chip that includes a pair of semiconductor chips disposed on a pair of die regions and a scribe lane region connecting the pair of semiconductor chips. The semiconductor chip may be a memory chip or a logic chip. For example, the semiconductor chip may be a core chip included in the high bandwidth memory (HBM) device. However, it will be appreciated that example embodiments are not limited thereto.

The die region may be a region in which circuits are formed, and the scribe lane region may be a region dividing (e.g., between) die regions. For example, the double-chip structure 30 may be a semiconductor chip that is formed by removing scribe lane regions surrounding the pair of die regions, while the scribe lane region connecting the pair of die regions is not removed.

In example embodiments, the first double-chip structure 100 may include a first semiconductor chip 100a, a second semiconductor chip 100b, and a first scribe lane region SR1 between the first semiconductor chip 100a and the second semiconductor chip 100b. For example, the first double-chip structure 100 may include the first semiconductor chip 100a disposed in a first die region DR1, the second semiconductor chip 100b in a second die region DR2 spaced apart from the first die region DR1 in a first horizontal direction HD1, and a first connection portion 115 disposed in the first scribe lane region SR1 and connecting the first semiconductor chip 100a and the second semiconductor chip 100b.

The first semiconductor chip 100a may include a first semiconductor substrate 110a having a first surface 112a and a second surface 114a extending in the first horizontal direction HD1 and facing away from each other, a first insulation layer 120a provided on the first surface 112a of the first semiconductor substrate 110a, a plurality of first chip pads 130a provided in the first insulation layer 120a to be at least partially exposed from the first insulation layer 120a, a plurality of second chip pads 140a provided on the second surface 114a of the first semiconductor substrate 110a, and a plurality of first conductive connection bumps 160a respectively provided on the plurality of first chip pads 130a. In addition, the first semiconductor chip 100a may further include a plurality of first through vias 150a penetrating the first semiconductor substrate 110a and electrically connecting the plurality of first chip pads 130a and the plurality of second chip pads 140a. For example, the first surface 112a may be an active surface on which circuits are formed, and the second surface 114a may be an inactive surface.

Although a few pads (e.g., first chip pads 130a and second chip pads 140a) are illustrated in the figures, it will be appreciated that example embodiments are not limited thereto. Accordingly, the number, size, arrangement, shape, etc., of the pads may be varied. Additionally, although a few through vias (e.g., first through vias 150a) are illustrated in the figures, it will be appreciated that example embodiments are not limited thereto. For example, the double-chip structure may not include through vias. Further, the number, size, arrangement, shape, etc., of the through vias may be varied.

According to some embodiments, the semiconductor substrate (e.g., the first semiconductor substrate 110a) may have internal wirings electrically connecting the pads (e.g., the first chip pads 130a and the second chip pads 140a).

The plurality of first chip pads 130a may be disposed on the first surface 112a of the first semiconductor substrate 110a in the first die region DR1. Additionally, the plurality of second chip pads 140a may be disposed on the second surface 114a of the first semiconductor substrate 110a in the first die region DR1. For example, the plurality of first chip pads 130a and the plurality of second chip pads 140a may include a conductive metallic material for electrical connection.

The plurality of first through vias 150a may be disposed in the first die region DR1 to penetrate the first semiconductor substrate 110a. Additionally, the plurality of first conductive connection bumps 160a may be provided on the plurality of first chip pads 130a in the first die region DR1, respectively. For example, the plurality of first through vias 150a and the plurality of first conductive connection bumps 160a may include a conductive metallic material for electrical connection.

The second semiconductor chip 100b may include a second semiconductor substrate 110b having a first surface 112b and a second surface 114b extending in the first horizontal direction HD1 and facing away each other, a second insulation layer 120b provided on the first surface 112b of the second semiconductor substrate 110b, a plurality of third chip pads 130b provided in the second insulation layer 120b to be at least partially exposed from the second insulation layer 120b, a plurality of fourth chip pads 140b provided on the second surface 114b of the second semiconductor substrate 110b, and a plurality of second conductive connection bumps 160b respectively provided on the plurality of third chip pads 130b. In addition, the second semiconductor chip 100b may further include a plurality of second through vias 150b penetrating the second semiconductor substrate 110b and electrically connecting the plurality of third chip pads 130b and the plurality of fourth chip pads 140b. For example, the first surface 112b may be an active surface on which a circuit is formed, and the second surface 114b may be an inactive surface.

Although a few pads (e.g., third chip pads 130b and fourth chip pads 140b) are illustrated in the figures, it will be appreciated that example embodiments are not limited thereto. Accordingly, the number, size, arrangement, shape, etc., of the pads may be varied. Additionally, although a few through vias (e.g., second through vias 150b) are illustrated in the figures, it will be appreciated that example embodiments are not limited thereto. Thus, the double-chip structure may not include through vias. Further, the number, size, arrangement, shape, etc., of the through vias may be varied.

According to some embodiments, the semiconductor substrate (e.g., the second semiconductor substrate 110b) may have internal wirings electrically connecting the pads (e.g., the third chip pads 130b and the fourth chip pads 140b).

The plurality of third chip pads 130b may be disposed on the second surface 114b of the second semiconductor substrate 110b in the second die region DR2. Additionally, the plurality of fourth chip pads 140b may be disposed on the second surface 114b of the second semiconductor substrate 110b in the second die region DR2. For example, the plurality of third chip pads 130b and the plurality of fourth chip pads 140b may include a conductive metallic material for electrical connection.

The plurality of second through vias 150b may be disposed in the second die region DR3 to penetrate the second semiconductor substrate 110b. Additionally, the plurality of second conductive connection bumps 160b may be provided on the plurality of third chip pads 130b in the second die region DR2, respectively. For example, the plurality of second through vias 150b and the plurality of second conductive connection bumps 160b may include a conductive metallic material for electrical connection. The first double-chip structure 100 may be mounted on the chip mounting region MR of the substrate structure 20 via the plurality of first conductive connection members (e.g., the first conductive connection bumps 160a and the second conductive connection bumps 160b) that are respectively provided between the plurality of first substrate pads 23 and the plurality of first and third chip pads (e.g., the first chip pads 130a, and the third chip pads 130b) such that the first surfaces 112a and 112b of the first double-chip structure 100 face the first surface 20a of the substrate structure 20. For example, the first double-chip structure 100 may be mounted on the substrate structure 20 to form a first gap G1 between the first insulation layer 120a and the second insulation layer 120b of the first double-chip structure 100 and the substrate structure 20.

The first double-chip structure 100 may include a first penetration portion PP1 disposed in the first scribe lane region SR1 to penetrate the first connection portion 115. The first penetration portion PP1 may be a passage at least partially filled by the molding member 40 as will be described below. For example, the first penetration portion PP1 may include a plurality of first through holes PH1.

Each of the plurality of first through holes PH1 may have a circular shape when viewed in a plan view. Additionally, the plurality of first through holes PH1 may be arranged in a direction different from the first horizontal direction HD1 to be spaced apart from each other. For example, the plurality of first through holes PH1 may be arranged along a second horizontal direction HD2 perpendicular to the first horizontal direction HD1.

Each of the plurality of first through holes PH1 may have a first diameter W1. For example, the first diameter W1 may have a predetermined size along a vertical direction VD.

Although a few through holes (e.g., first through holes PH1) are illustrated in the figures, it will be appreciated that example embodiments are not limited thereto. Accordingly, the number, size, arrangement, shape, etc., of the through holes may be varied.

In example embodiments, the second double-chip structure 200 may include a third semiconductor chip 200a, a fourth semiconductor chip 200b, and a second scribe lane region SR2 between the third semiconductor chip 200a and the fourth semiconductor chip 200b. For example, the second double-chip structure 200 may include the third semiconductor chip 200a disposed in a third die region DR3, the fourth semiconductor chip 200b in a fourth die region D4 spaced apart from the third die region DR3 in the first horizontal direction HD1, and a second connection portion 215 disposed in the second scribe lane region SR2 and connecting the third semiconductor chip 200a and the fourth semiconductor chip 200b.

The third semiconductor chip 200a may include a third semiconductor substrate 210a having a first surface 212a and a second surface 214a extending in the first horizontal direction HD1 and facing away from each other, a third insulation layer 220a provided on the first surface 212a of the third semiconductor substrate 210a, a plurality of fifth chip pads 230a provided in the third insulation layer 220a to be at least partially exposed from the third insulation layer 220a, and a plurality of third conductive connection bumps 260a respectively provided on the plurality of fifth chip pads 230a. For example, the first surface 212a may be an active surface on which circuits are formed, and the second surface 214a may be an inactive surface.

Although a few pads (e.g., fifth chip pads 230a) are illustrated in the drawings, it will be appreciated that example embodiments are not limited thereto. Accordingly, the number, size, arrangement, shape, etc., of the pads may be varied. Additionally, according to some embodiments, the semiconductor substrates (e.g., the third semiconductor substrate 210a) may have internal wirings electrically connecting the pads (e.g., the fifth chip pads 23a).

The plurality of fifth chip pads 230a may be disposed on the first surface 212a of the third semiconductor substrate 210a in the third die region DR3. For example, the plurality of fifth chip pads 230a may include a conductive metallic material for electrical connection.

The plurality of third conductive connection bumps 260a may be provided on the plurality of fifth chip pads 230a in the third die region DR3, respectively. For example, the plurality of third conductive connection bumps 260a may include a conductive metallic material for electrical connection.

The fourth semiconductor chip 200b may include a fourth semiconductor substrate 210b having a first surface 212b and a second surface 214b extending in the first horizontal direction HD1 and facing away from each other, a fourth insulation layer 220b provided on the first surface 212b of the fourth semiconductor substrate 210b, a plurality of sixth chip pads 230b provided in the fourth insulation layer 220b to be at least partially exposed from the fourth insulation layer 220b, and a plurality of fourth conductive connection bumps 260b respectively provided on the plurality of sixth chip pads 230b. For example, the first surface 212b may be an active surface on which a circuit is formed, and the second surface 214b may be an inactive surface.

Although a few pads (e.g., sixth chip pads 230b) are illustrated in the figures, it will be appreciated that example embodiments are not limited thereto. Accordingly, the number, size, arrangement, shape, etc., of the pads may be varied. Additionally, although internal wirings of the semiconductor substrate (e.g., the fourth semiconductor substrate 210b) are not illustrated in the figures, the semiconductor substrate may have internal wirings electrically connecting the pads (e.g., the sixth chip pads 230b).

The plurality of sixth chip pads 230b may be disposed on the first surface 212b of the fourth semiconductor substrate 210b in the fourth die region DR4. For example, the plurality of sixth chip pads 230b may include a conductive metallic material for electrical connection.

The plurality of fourth conductive connection bumps 260b may be provided on of the plurality of sixth chip pads 230b in the fourth die region DR4, respectively. For example, the plurality of fourth conductive connection bumps 260b may include a conductive metallic material for electrical connection.

The second double-chip structure 200 may be mounted on the first double-chip structure 100 via the plurality of second conductive connection members (e.g., the third conductive connection bumps 260a and the fourth conductive connection bumps 260b) that are respectively provided between the plurality of second and fourth chip pads (e.g., the second chip pads 140a and the fourth chip pads 140b) and the plurality of fifth and sixth chip pads (e.g., the fifth chip pads 230a and the sixth chip pads 230b) such that the first surfaces 212a and 212b of the second double-chip structure 200 face the first surface 20a of the substrate structure 20. For example, the second double-chip structure 200 may be mounted on the substrate structure 20 to form a second gap G2 between the third and fourth insulation layers (e.g., the third insulation layer 220a and the fourth insulation layer 220b) of the second double-chip structure 200 and the first and second insulation layers (e.g., the first insulation layer 120a and the second insulation layer 120b) of the first double-chip structure 100.

The second double-chip structure 200 may include a second penetration portion PP2 disposed in the second scribe lane region SR2 and penetrating the second connection portion 215. The second penetration portion PP2 may be a passage at least partially filled by the molding member 40 as will be described below. For example, the second penetration portion PP2 may include a plurality of second through holes PH2.

Each of the plurality of second through holes PH2 may have a circular shape when viewed in a plan view. Additionally, the plurality of second through holes PH2 may be arranged in a direction different from the first horizontal direction HD1 to be spaced apart from each other. For example, the plurality of second through holes PH2 may be arranged along the second horizontal direction HD2 perpendicular to the first horizontal direction HD1.

Each of the plurality of second through holes PH2 may have a second diameter W2. For example, the second diameter may have a predetermined size along the vertical direction VD.

Although a few through holes (e.g., second through holes PH2) are illustrated in the figures, it will be appreciated that example embodiments are not limited thereto. Accordingly, the number, size, arrangement, shape, etc., of the through holes may be varied.

The third semiconductor chip 200a may be stacked on the first semiconductor chip 100a, and the fourth semiconductor chip 200b may be stacked on the second semiconductor chip 100b. For example, each of the third conductive connection bumps 260a may be disposed between the third chip pad 130b of the first semiconductor chip 100a and the fifth chip pad 230a of the third semiconductor chip 200a to electrically connect the first semiconductor chip 100a and the third semiconductor chip 200a, and each of the fourth conductive connection bumps 260b may be disposed between the fourth chip pad 140b of the second semiconductor chip 100b and the sixth chip pad 230b of the fourth semiconductor chip 200b to electrically connect the second semiconductor chip 100b and the fourth semiconductor chip 200b.

The first connection portion 115 of the first double-chip structure 100 and the second connection portion 215 of the second double-chip structure 200 may overlap with each other when viewed in a plan view (e.g., overlap in the vertical direction VD). Additionally, each of the plurality of first through holes PH1 of the first double-chip structure 100 and each of the plurality of second through holes PH2 of the second double-chip structure 200 may overlap with each other when viewed in a plan view (e.g., overlap in the vertical direction VD). For example, each of the plurality of the first through holes PH1 and each of the plurality of the second through holes PH2 may be aligned in the vertical direction VD. The first diameter W1 of each of the plurality of the first through holes PH1 may be the same as the second diameter W2 of each of the plurality of the second through holes PH2. However, this embodiment is provided as an example, so it will be appreciated that example embodiments are not limited thereto. Accordingly, the arrangements and widths of the plurality of first through holes and the plurality of second through holes may be varied.

In example embodiments, the molding member 40 may be provided on the first surface 20a of the substrate structure 20 to cover the first double-chip structure 100 and the second double-chip structure 200. For example, the molding member 40 may include a thermosetting material that hardens when heat is applied. The molding member 40 may include an epoxy molding compounds (EMC). For example, the molding member 40 may be configured to physically protect the plurality of double-chip structures 30. Further, the molding member 40 may serve as an underfill to protect the first and second conductive connection members (e.g., the first conductive connection bumps 160a, the second conductive connection bumps 160b, the third conductive connection bumps 260a, and the fourth conductive connection bumps 260b) of the plurality of double-chip structures 30.

The molding member 40 may be provided on the substrate structure 20 and may at least partially fill the plurality of first through holes PH1, the plurality of second through holes PH2, the first gap G1, and the second gap G2.

As mentioned above, the semiconductor package 10 may include the substrate structure 20, the first double-chip structure 100, and the second double-chip structure 200 mounted sequentially on the substrate structure 20, and may further include the molded member 40 covering the first double-chip structure 100 and the second double-chip structure 200.

The first double-chip structure 100 may include the pair of first semiconductor chips (e.g., the first semiconductor chip 100a and the second semiconductor chip 100b) and the first scribe lane region SR1 connecting the pair of first semiconductor chips (e.g., the first semiconductor chip 100a and the second semiconductor chip 100b). The second double-chip structure 200 may include the pair of second semiconductor chips (e.g., the third semiconductor chip 200a and the fourth semiconductor chip 200b) and the second scribe lane region SR2 connecting the pair of second semiconductor chips (e.g., the third semiconductor chip 200a and the fourth semiconductor chip 200b).

The first double-chip structure 100 may include the plurality of first through holes PH1 disposed in the first scribe lane region SR1. The second double-chip structure may include the plurality of second through holes PH2 disposed in the second scribe lane region SR2.

Accordingly, a molding material for forming the molding member 40 may be moved toward a central portion of the first double-chip structure 100 and a central portion of the second double-chip structure 200 through the plurality of first through holes PH1 and the plurality of second through holes PH2. Accordingly, a flow speed difference of the molding material may be reduced. Thus, the first through holes PH1 and the second through holes PH2 may prevent voids from occurring at a space below the first double-chip structure 100 as the lowermost chip, to thereby prevent the first conductive connecting members (e.g., the first conductive connection bumps 160a, and the second conductive connection bumps 160b) of the first double-chip structure 100 from being pressed.

Hereinafter, a method of manufacturing the semiconductor package 10 of FIG. 1 will be described.

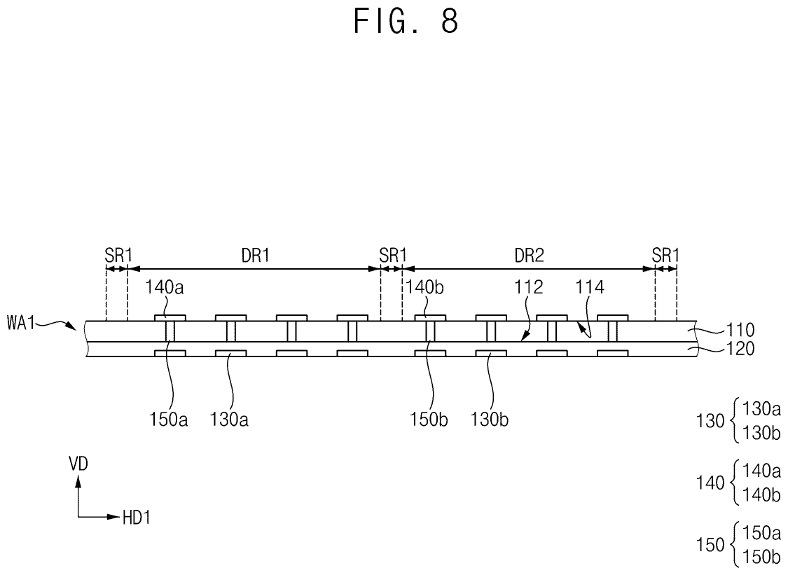

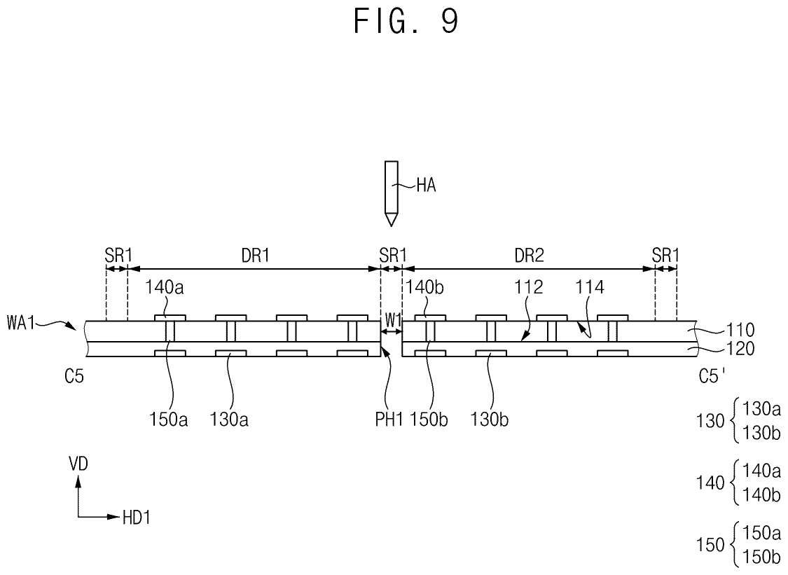

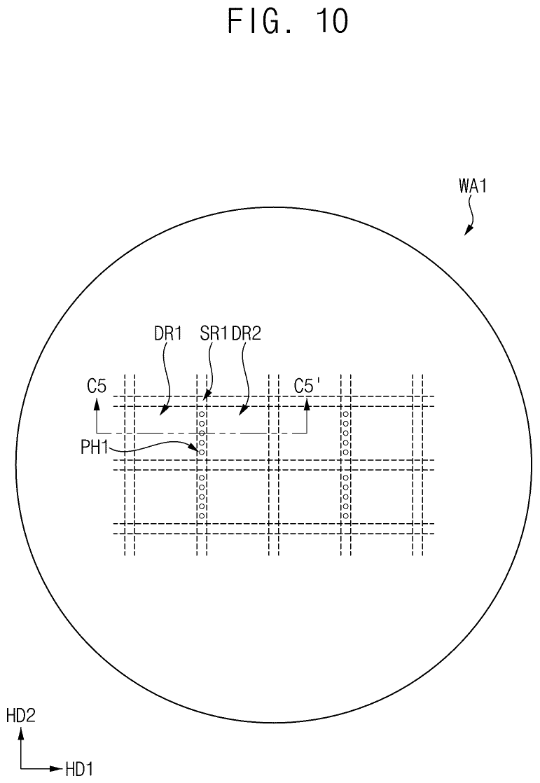

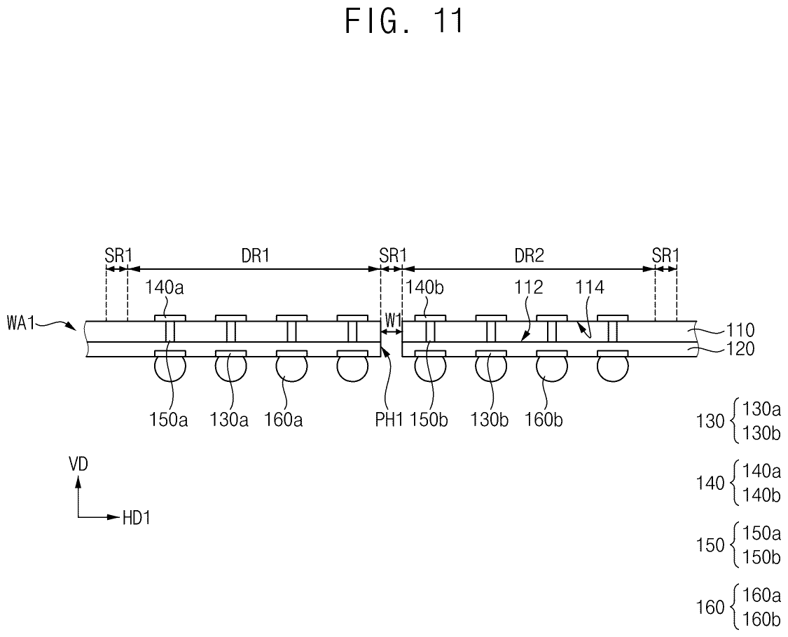

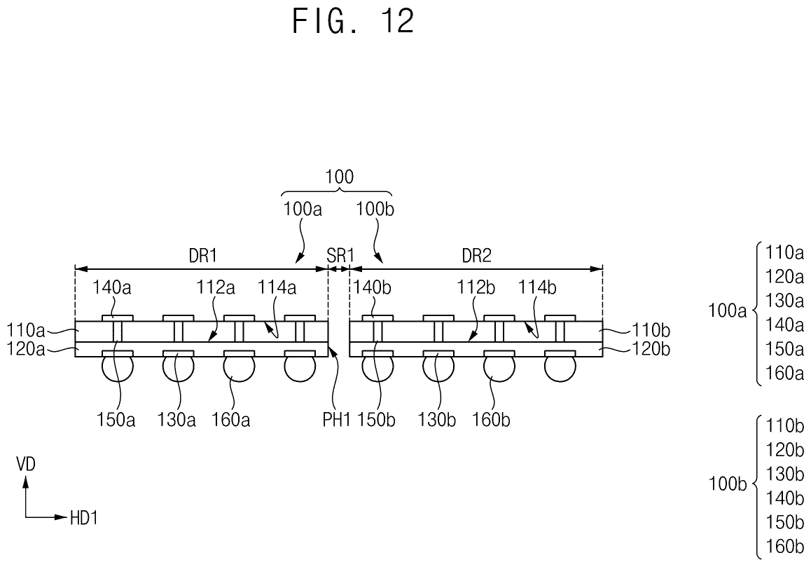

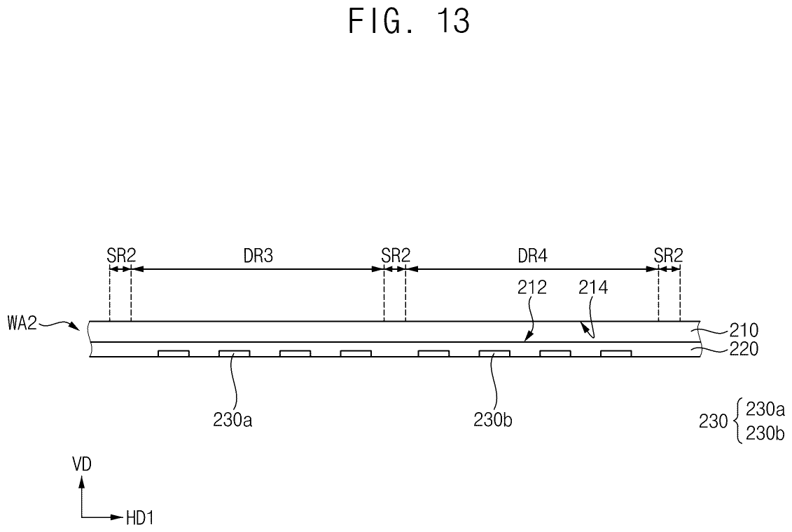

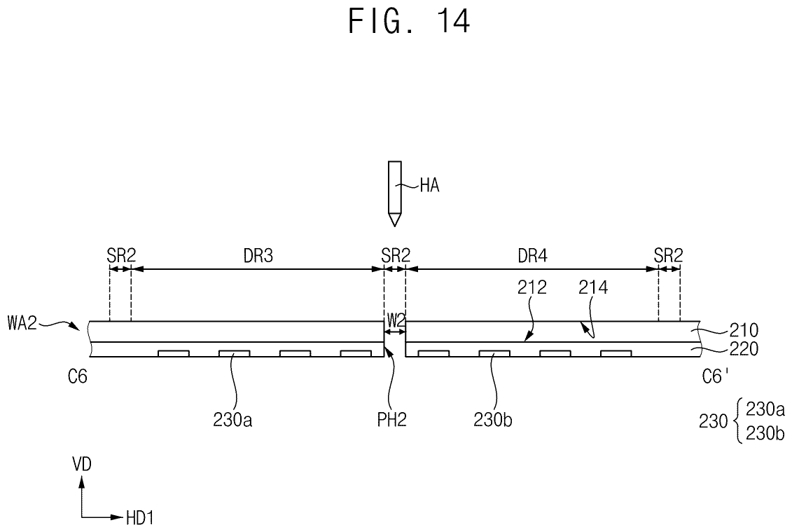

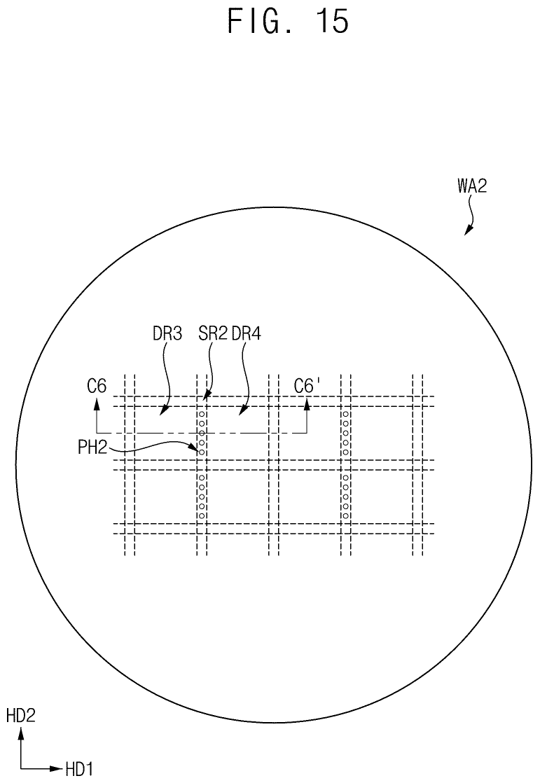

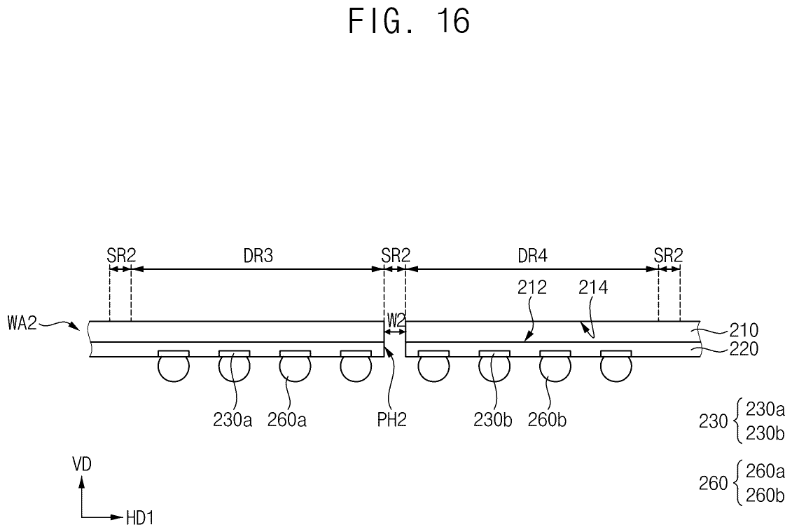

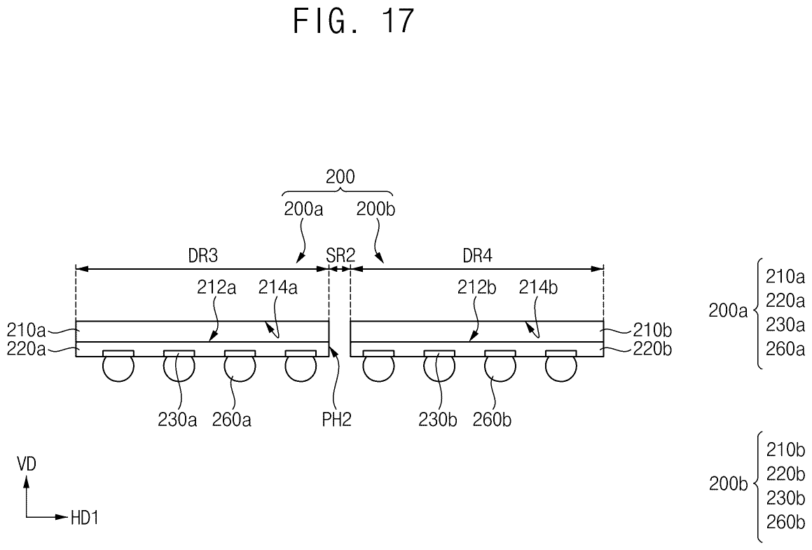

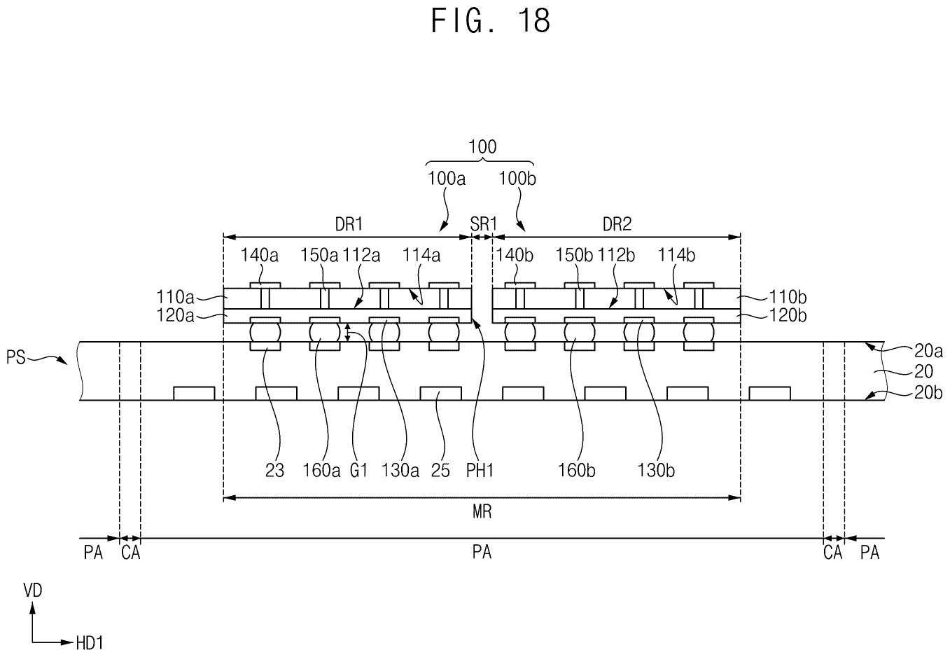

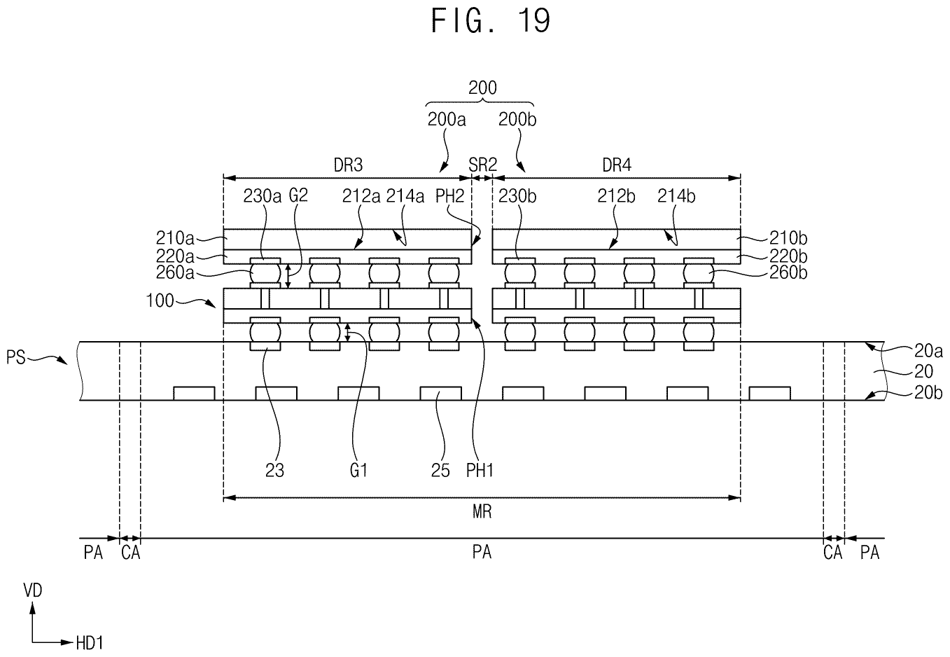

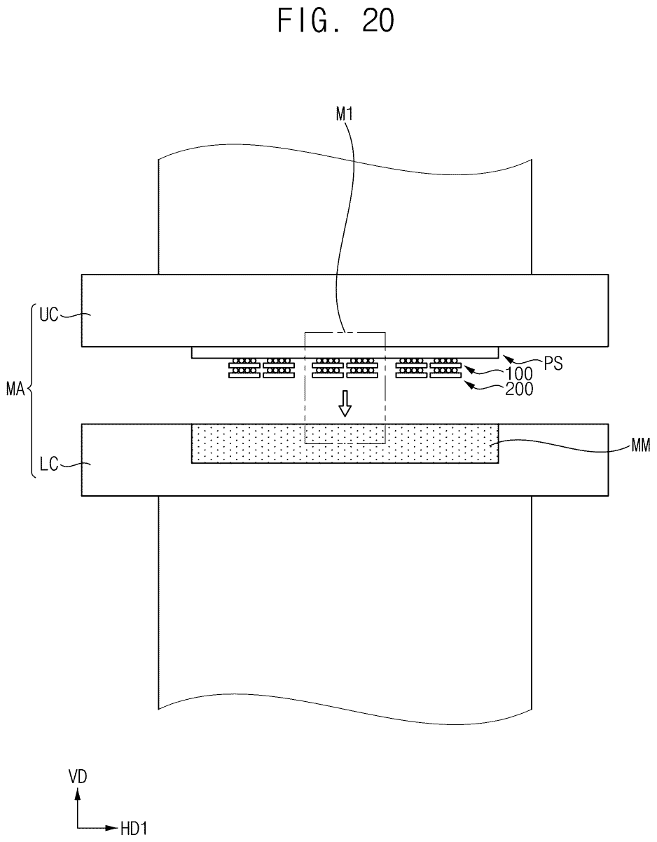

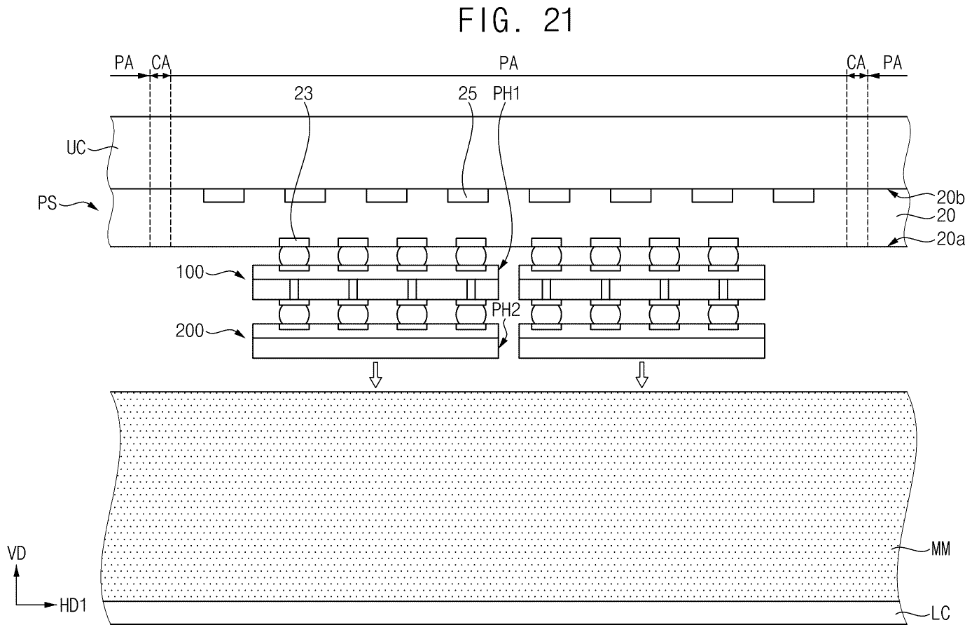

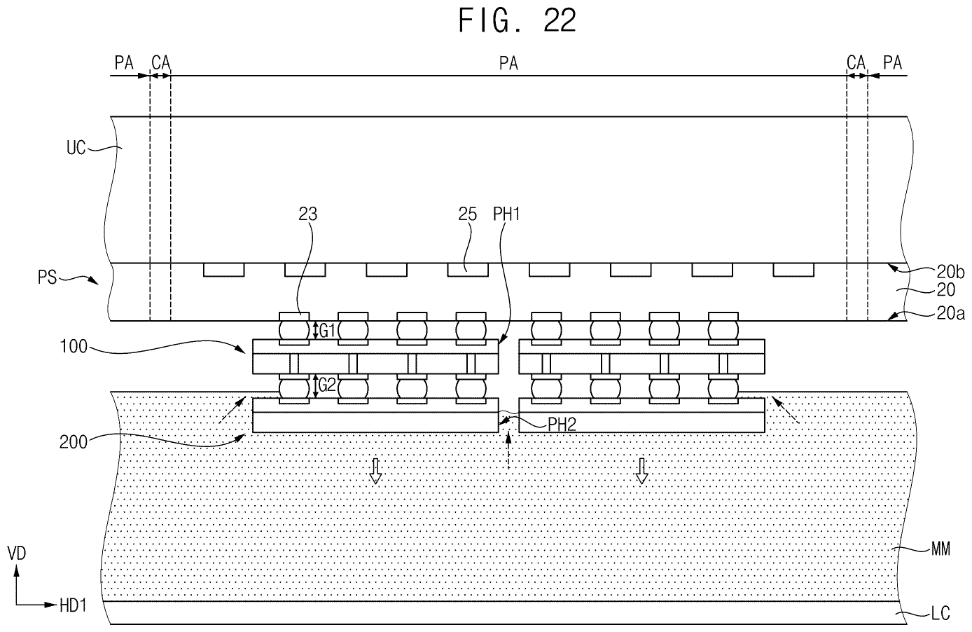

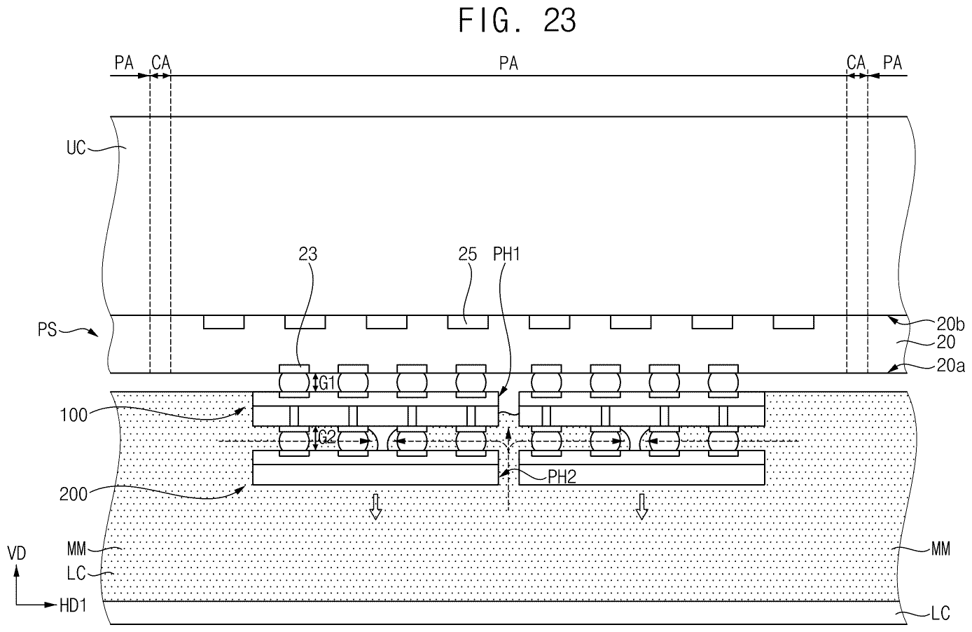

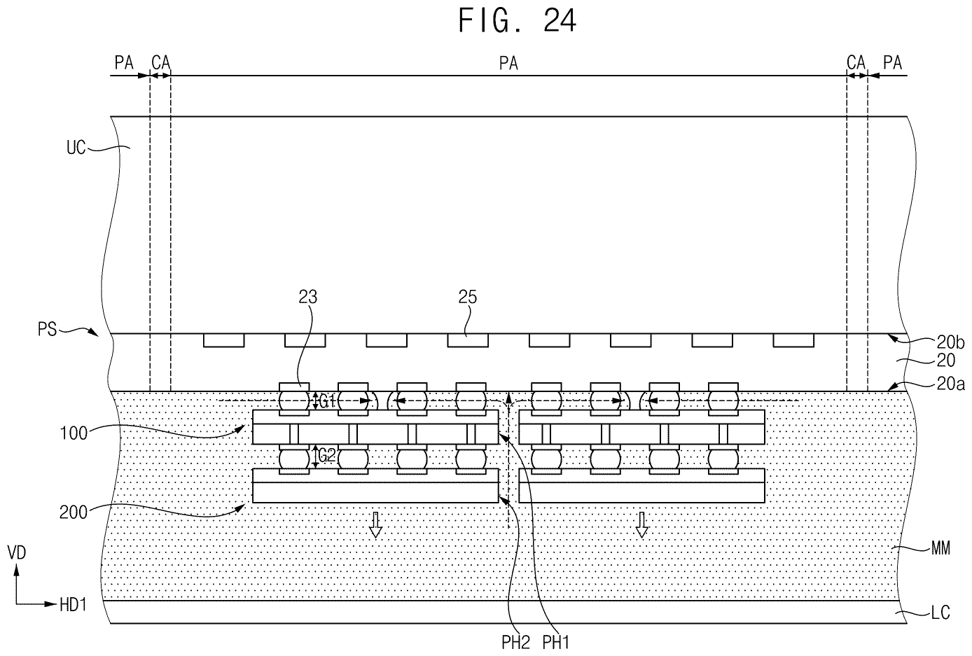

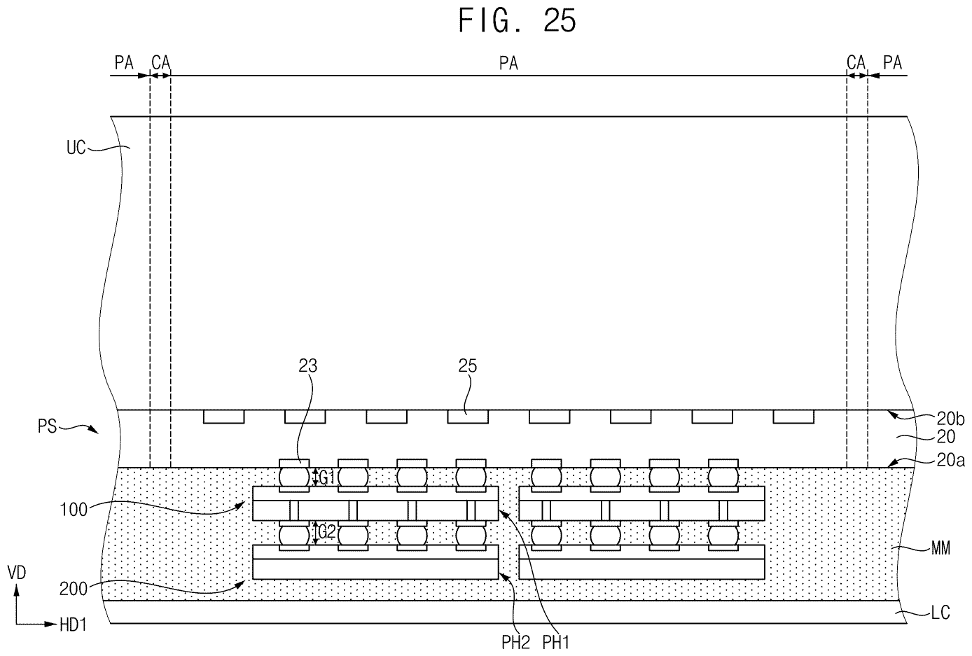

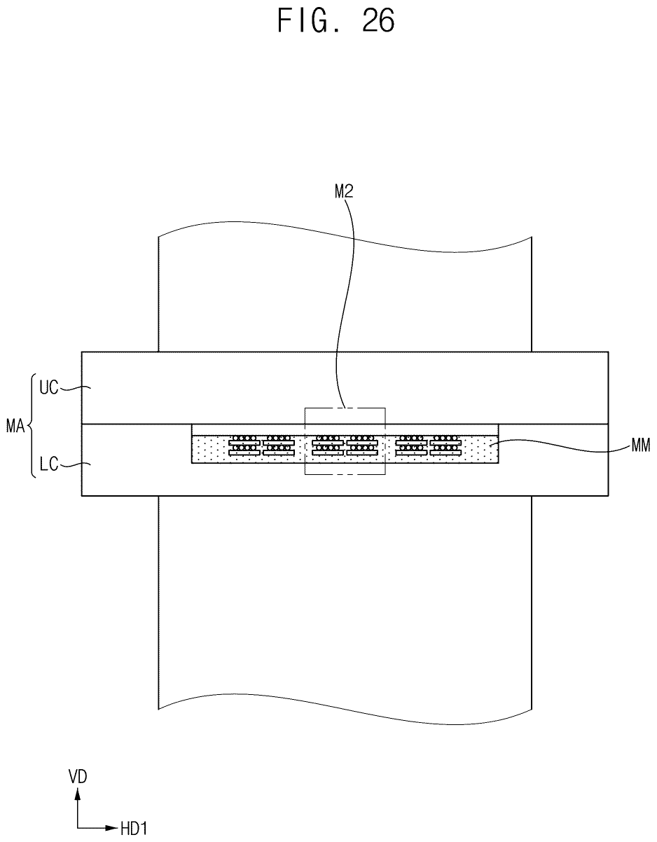

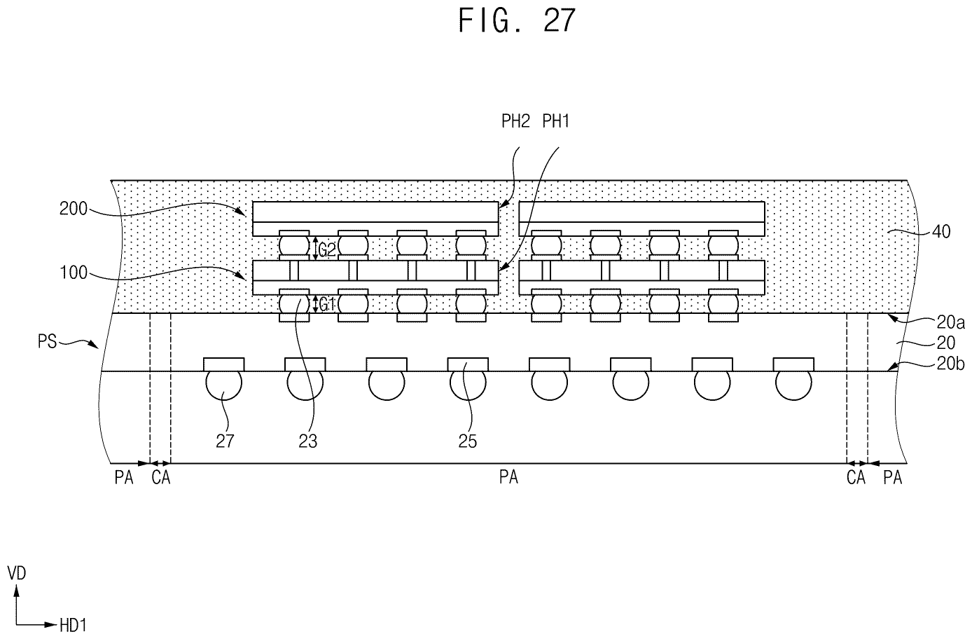

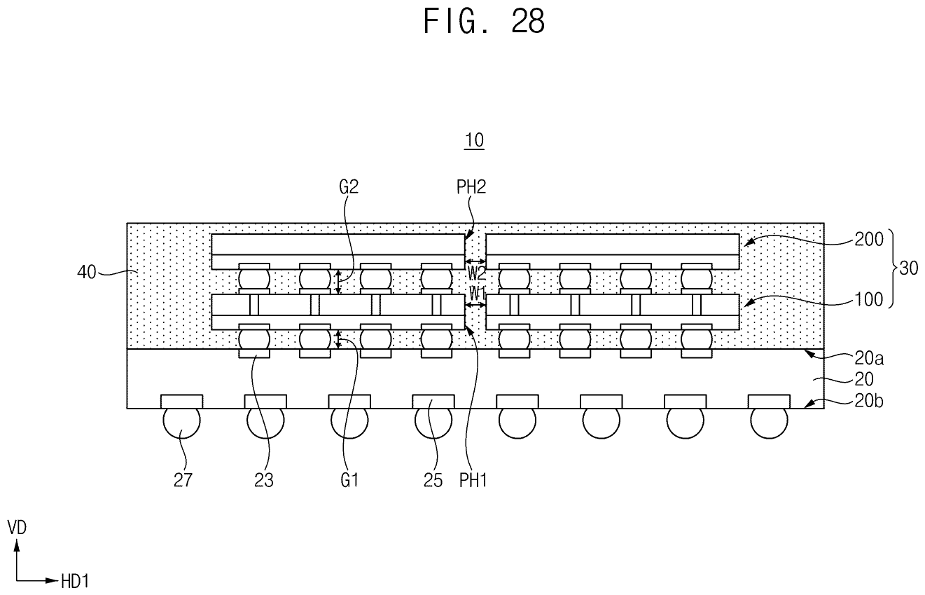

FIG. 8 is a cross-sectional view illustrating a first wafer in accordance with example embodiments. FIG. 9 is a cross-sectional view illustrating a process of forming through holes in the first wafer of FIG. 8. FIG. 10 is a plan view illustrating the first wafer of FIG. 9. FIG. 9 is a cross-sectional view taken along a line C5-C5′ of FIG. 10. FIG. 11 is a cross-sectional view illustrating a process of attaching conductive connection members on the first wafer of FIG. 9. FIG. 12 is a cross-sectional view illustrating a process of cutting the first wafer of FIG. 11 to form a first double-chip structure. FIG. 13 is a cross-sectional view illustrating a second wafer in accordance with example embodiments. FIG. 14 is a cross-sectional view illustrating a process of forming through holes in the second wafer of FIG. 13. FIG. 15 is a plan view illustrating the second wafer of FIG. 14. FIG. 14 is a cross-sectional view taken along a line C6-C6′ of FIG. 15. FIG. 16 is a cross-sectional view illustrating a process of attaching conductive connection members on the second wafer of FIG. 14. FIG. 17 is a cross-sectional view illustrating a process of cutting the second wafer of FIG. 16 to form a second double-chip structure. FIGS. 18 and 19 are views illustrating a process of mounting the first and second double-chip structures on a substrate structure. FIGS. 20 to 26 are views illustrating a process of forming a molding member to cover the first and second double-chip structures of FIG. 19. FIG. 21 is an enlarged cross-sectional view illustrating a portion “M1” of FIG. 20. FIG. 25 is an enlarged cross-sectional view illustrating a portion “M2” of FIG. 26. FIG. 27 is a cross-sectional view illustrating a process attaching external connection members on the substrate structure of FIG. 26. FIG. 28 is a cross-sectional view illustrating a process of cutting the substrate structure of FIG. 27 to complete a semiconductor package.

Since the semiconductor package manufactured by the manufacturing process illustrated in FIGS. 8 to 28 may be substantially the same as the semiconductor package described with reference to FIGS. 1 to 7, identical components are denoted by the same reference numerals, and repeated descriptions of identical components may be omitted.

Referring to FIGS. 8 to 12, a first wafer WA1 having a first die region DR1, a second die region DR2, and a first scribe lane region SR1 dividing (e.g., between) the first die region DR1 and the second die region DR2 may be provided, a plurality of first through holes PH1 may be formed in the first scribe lane region SR1, a plurality of first conductive connection members (e.g., first conductive connection bumps 160a, and second conductive connection bumps 160b) may be attached to the first wafer WA1, and a portion of the first scribe lane region SR1 in which the plurality of first through holes PH1 are not formed, may be removed, to form a first double-chip structure 100.

For example, the first wafer WA1 may include a first substrate 110 having a first surface 112 and a second surface 114 extending in a first horizontal direction HD1 and facing away from each other, a first insulation layer 120 provided on the first surface 112 of the first semiconductor substrate 110a, a plurality of first pads 130 provided in the first insulation layer 120 to be at least partially exposed from the first insulation layer 120, a plurality of second chip pads 140 provided on the second surface 114 of the first substrate 110, and a plurality of conductive vias 150 penetrating the first substrate 110 and electrically connecting the plurality of first pads 130 and the plurality of second chip pads 140.

The plurality of first through holes PH1 may be formed in a portion of the first scribe lane region SR1 of the first wafer WA1 and may be arranged in the second horizontal direction HD2 to be spaced apart from each other. For example, the plurality of first through holes PH1 may be formed in the portion of the first scribe lane region SR1 between the first die region DR1 and the second die region DR2. For example, the plurality of first through holes PH1 may be formed by a drilling process. For example, in the drilling process, a drilling apparatus HA may be positioned above the first scribe lane region SR1 and the portion of the first scribe lane region SR1 may be removed to form the plurality of first through holes PH1.

Although the drilling process is illustrated as being performed in the figures, it will be appreciated that example embodiments are not limited thereto. For example, a laser process or an etching process may be performed to form the plurality of first through holes PH1. In the case of the laser process, a laser apparatus may be positioned above the first scribe lane region SR1, and may irradiate the first scribe lane region SR1 with light to form the plurality of first through holes PH1. In the case of the etching process, an etching mask having openings that expose regions corresponding to the plurality of first through holes PH1 may be formed on the first wafer WA1, and an etchant may be sprayed onto the etching mask to form the plurality of first through holes PH1.

As illustrated in FIG. 10, for example, the first scribe lane regions SR1 of the first wafer WA1 may be arranged to be spaced apart along the first horizontal direction HD1, and each of the first scribe lane regions SR1 may extend in the second horizontal direction HD2. The first through holes PH1 may be formed in every other one of the first scribe lane regions SR1.

Referring to FIGS. 13 to 17, a second wafer WA2 having a third die region DR3, a fourth die region DR4, and a second scribe lane region SR2 dividing (e.g., between) the third die region DR3 and the fourth die region DR4 may be provided, and a plurality of second through holes PH2 may be formed in the second scribe lane region SR2, a plurality of second conductive connection members (e.g., third conductive connection bumps 260a, and fourth conductive connection bumps 260b) may be attached to the second wafer WA2, and a portion of the second scribe lane region SR2 in which the plurality of second through holes PH2 are not formed, may be removed, to form a second double-chip structure 200.

For example, the second wafer WA2 may include a second substrate 210 having a first surface 212 and a second surface 214 extending in the first horizontal direction HD1 and facing away from each other, a second insulation layer 220 provided on the first surface 212 of the second substrate 210, and a plurality of third pads 230 provided in the second insulation layer 220 to be at least partially exposed from the second insulation layer 220.

The plurality of second through holes PH2 may be formed in a portion of the second scribe lane region SR2 of the second wafer WA2 and may be arranged in a second horizontal direction HD2 to be spaced apart from each other. For example, the plurality of second through holes PH2 may be formed in the second scribe lane region SR2 provided between the third die region DR3 and the fourth die region DR4. For example, the plurality of second through holes PH2 may be formed by a drilling process. For example, in the drilling process, a drilling apparatus HA may be positioned above the second scribe lane region SR2 and the portion of the second scribe lane region SR2 may be removed to form the plurality of second through holes PH2.

Although the drilling process is illustrated as being performed in the figures, it will be appreciated that example embodiments are not limited thereto. For example, a laser process or an etching process may be performed to form the plurality of second through holes PH2. In the case of the laser process, a laser apparatus may be positioned above the second scribe lane region SR2, and may irradiate the second scribe lane region SR2 with light to form the plurality of second through holes PH2. In the case of an etching process, an etching mask having openings that expose regions corresponding to the plurality of second through holes PH2 may be formed on the second wafer WA2, and an etchant may be sprayed onto the etching mask to form the plurality of second through holes PH2.

As illustrated of FIG. 15, for example, the second scribe lane regions SR2 of the second wafer WA2 may be arranged to be spaced apart along the first horizontal direction HD1, and each of the second scribe lane regions SR2 may extend in the second horizontal direction HD2. The second through holes PH2 may be formed in every other one of the second scribe lane regions SR2.

Referring to FIGS. 18 and 19, a substrate strip PS having a plurality of package regions PA and a cutting region CA dividing the plurality of package regions PA may be provided, the first double-chip structure 100 may be mounted on a mounting region MR of each of the plurality of package regions PA of the substrate strip PS, and the second double-chip structure 200 may be mounted on the first double-chip structure 100. For example, the package region PA may be a region where the first and second double-chip structures are mounted, and the cutting region may be a region that is removed by a cutting process as will be described later. For example, the substrate strip may be a structure including a plurality of substrate structures. The substrate structures may include a printed circuit board (PCB), an interposer, and the like. Further, the substrate structure may be a wafer including a plurality of chips. For example, the substrate structure may be a wafer including a plurality of buffer chips included in a high bandwidth memory device. However, it will be appreciated that example embodiments are not limited thereto.

For example, the plurality of first conductive connection bumps 160a and the plurality of second conductive connection bumps 160b that are respectively provided between the first pads 130 of the first double-chip structure 100 and first substrate pads 23 of the substrate structure 20 to form a first gap G1 between the first double-chip structure 100 and the substrate strip PS may be heated and cooled by a reflow process, to electrically connect the substrate strip PS and the first double-chip structure 100.

Then, the plurality of third conductive connection bumps 260a and the plurality of fourth conductive connection bumps 260b that are respectively provided between the third pads 230 of the second double-chip structure 200 and the second chip pads 140 of the first double-chip structure 100 to form a second gap G2 between the second double-chip structure 200 and the first double-chip structure 100 may be heated and cooled by a reflow process, to electrically connect the first double-chip structure 100 and the second double-chip structure 200.

Referring to FIGS. 20 to 26, a molding apparatus MA that has a lower mold LC and an upper mold UC facing each other may be provided, and the substrate strip PS on which the first double-chip structure 100 and the second double-chip structure 200 are mounted, may be loaded onto the upper mold UC of the molding apparatus MA, and the upper mold UC may move toward the lower mold LC such that the substrate strip PS that is supported fixedly by the upper mold UC is immersed in a molding material MM within a receiving space of the lower mold LC. For example, the molding material may be in a liquid state or in a particulate state such as a pellet or powder.

For example, the substrate strip PS may be fixed to the upper mold UC such that a first surface 20a of the substrate strip PS faces the lower mold LC. The first surface of the substrate strip PS may be a surface on which the first double-chip structure 100 and the second double-chip structure 200 are mounted.

Then, the upper mold UC may move toward the lower mold LC such that the second double-chip structure 200 mounted on the substrate scribe PS is immersed in the molding material MM. For example, the molding material MM may move from a peripheral region of the second gap G2 to a central region of the second gap G2. In this case, the plurality of second through holes PH2 of the second double-chip structure 200 may provide passages through which the molding material MM moves to fill the central region of the second gap G2.

Accordingly, the plurality of second through holes PH2 may reduce a flow speed difference of the molding material MM between the peripheral region of the second gap G2 and the central region of the second gap G2, thereby preventing voids from occurring inside the second gap G2.

Then, the upper mold UC may move further toward the lower mold LC such that the first double-chip structure 100 mounted on the substrate strip PS is immersed in the molding material MM. For example, the molding material MM may move from a peripheral region of the first gap G1 to a central region of the first gap G1. In this case, the plurality of first through holes PH1 of the first double-chip structure 100 may provide passages through which the molding material MM moves to fill the central region of the first gap G1.

Accordingly, the plurality of first through holes PH1 may reduce a flow speed difference of the molding material MM between the peripheral region of the first gap G1 and the central region of the first gap G1, thereby preventing voids from occurring inside the first gap G1.

The plurality of first through holes PH1 and the plurality of second through holes PH2 may provide passages through which the molding material MM move into the central region of the first gap G1, which is the empty space between the first double-chip structure 100 as the lowermost chip and the substrate strip PS. Thus, the flow speed difference of the molding member between the first gap G1 and the second gap G2 may be reduced. Accordingly, voids may be prevented from occurring in a space below the first double-chip structure 100 as the lowermost chip, and the first conductive connection bumps 160a and 160b as bumps of the first double-chip structure 100 may be prevented from being pressed.

Then, the molding material MM may be heated to form a molding member 40 that covers the first double-chip structure 100 and the second double-chip structure 200.

Referring to FIGS. 27 and 28, a plurality of external connection members 27 may be attached to a plurality of second substrate pads 25 of the substrate strip PS, and the cutting region of the substrate strip PS may be removed by using a blade, to thereby complete the semiconductor package 10.

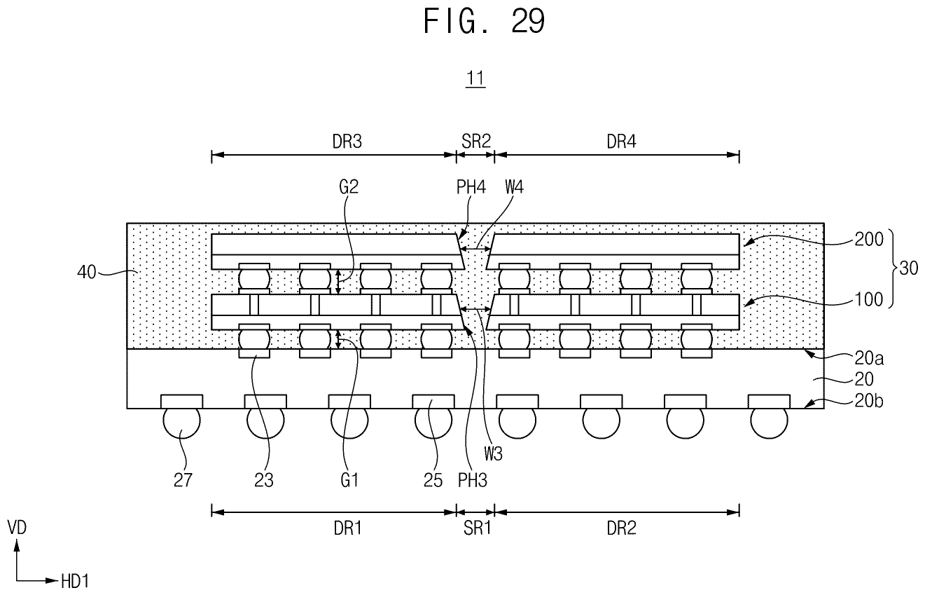

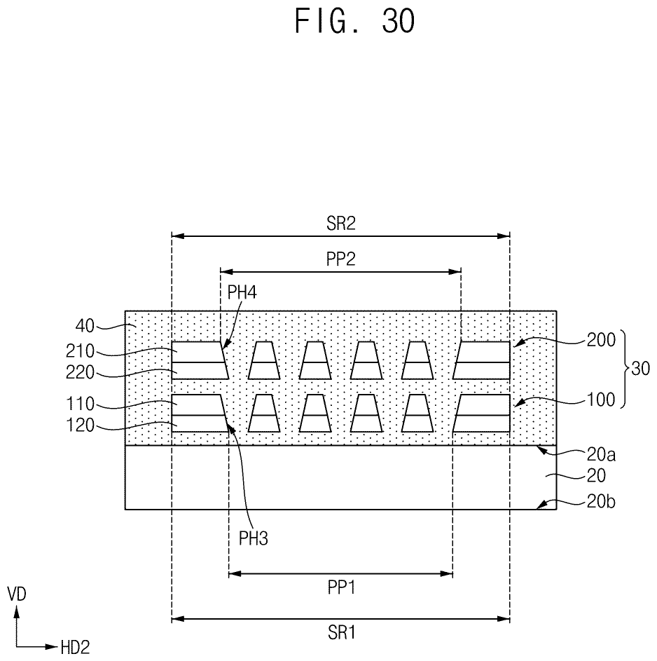

FIG. 29 is a cross-sectional view illustrating a semiconductor package in accordance with example embodiments. FIG. 30 is a cross-sectional view illustrating the semiconductor package of FIG. 29.

The semiconductor package illustrated in FIGS. 29 and 30 is substantially the same as the semiconductor package described with reference to FIGS. 1 to 7, except for shapes of third through holes PH3 and fourth through holes PH4, so identical components are denoted by the same reference numerals and repeated descriptions of identical components are omitted.

Referring to FIGS. 29 and 30, a semiconductor package 11 may include a substrate structure 20, a plurality of first double-chip structures 100 sequentially mounted on the substrate structure 20, and a molding member 40 provided on the substrate structure 20 to cover the plurality of first double-chip structures 100.

In example embodiments, the plurality of double-chip structures may include a first double-chip structure 100 and a second double-chip structure 200 sequentially mounted on a chip mounting regions MR of the substrate structure 20.

In example embodiments, the first double-chip structure 100 may include a first semiconductor chip 100a, a second semiconductor chip 100b, and a first scribe lane region SR1 dividing the first semiconductor chip 100a and the second semiconductor chip 100b. For example, the first double-chip structure 100 may include the first semiconductor chip 100a disposed in the first die region DR1, the second semiconductor chip 100b in a second die region DR2 spaced apart from the first die region DR1 in a first horizontal direction HD1, and a first connection portion 115 disposed in the first scribe lane region SR1 and connecting the first semiconductor chip 100a and the second semiconductor chip 100b.

The first double-chip structure 100 may include a first penetration portion PP1 disposed in the first scribe lane region SR1 to penetrate the first connection portion 115. For example, the first penetration portion PP1 may include a plurality of third through holes PH3.

In example embodiments, the second double-chip structure 200 may include a third semiconductor chip 200a, a fourth semiconductor chip 200b, and a second scribe lane region SR2 dividing the third semiconductor chip 200a and the fourth semiconductor chip 200b. For example, the second double-chip structure 200 may include the third semiconductor chip 200a disposed in a third die region DR3, a fourth semiconductor chip 200b in a fourth die region DR4 spaced apart from the third die region DR3 in the first horizontal direction HD1, and a second connection portion 215 disposed in the second scribe lane region SR2 and connecting the third semiconductor chip 200a and the fourth semiconductor chip 200b.

The second double-chip structure 200 may include a second penetration portion PP2 disposed in the second scribe lane region SR2 to penetrate the second connection portion 215. For example, the second penetration portion PP2 may include a plurality of fourth through holes PH4.

Each of the plurality of third through holes PH3 and each of the plurality of fourth through holes PH4 may have a circular shape, when viewed in a plan view.

Each of the plurality of third through holes PH3 may have a third diameter W3 along the horizontal direction, and each of the plurality of fourth through holes PH4 may have a fourth diameter W4 along the horizontal direction. The third diameter and the fourth diameter may vary along a vertical direction VD.

Each of the third diameter W3 and the fourth diameter W4 may have a tapered shape. For example, each of the third diameter W3 and the fourth diameter W4 may become narrower as each of the third diameter W3 and the fourth diameter W4 get closer to the substrate structure 20. For example, each of the plurality of third through holes PH3 and each of the plurality of fourth through holes PH4 may have a trapezoidal shape, when viewed in cross-sectional view. Further, each of the plurality of third through holes PH3 and each of the plurality of fourth through holes PH4 may at least partially overlap with each other, when viewed in a plan view. For example, each of the plurality of third through holes PH3 and each of the plurality of fourth through holes PH4 may be aligned in the vertical direction VD.

However, this example embodiment is provided as an example, so it will be appreciated that example embodiments of the present disclosure are not limited thereto. Accordingly, the arrangements and widths of the third through holes and the fourth through holes may be varied.

As mentioned above, the semiconductor package 11 may include the substrate structure 20, the first double-chip structure 100 and the second double-chip structure 200 sequentially mounted on the substrate structure 20, and the molding member 40 covering the first double-chip structure 100 and the second double-chip structure 200.

The first double-chip structure 100 may have the third through-holes PH3 disposed in the first scribe lane region SR1, and the second double-chip structure 200 may have the fourth through-holes PH4 disposed in the second scribe lane region SR2.

Each of the third through-holes PH3 and the fourth through-holes PH4 may have a tapered structure whose diameter becomes narrower as each of the third through holes PH3 and the fourth through holes PH4 approaches the substrate structure 20.

Accordingly, since the third through hole PH3 and the fourth through hole PH4 have the tapered structure whose diameter becomes narrower as each of the third through hole PH3 and the fourth through hole PH4 approaches the substrate structure 20, a flow rate of a molding material through the third through hole PH3 and the fourth through hole PH4 may be increased. Thus, shapes of the third through holes PH3 and the fourth through holes PH4 may help to move the molding member 40 quickly to a central region of the first double-chip structure 100 and a central portion of the second double-chip structure 200, thereby reducing the flow speed difference of the molding member 40 between a peripheral region and the central region of the first double-chip structure 100 and between a peripheral region and the central region of the second double-chip structure 200. Thus, voids may be prevented from occurring in a space below the first double-chip structure 100 as the lowermost chip, and first conductive connection bumps 160a and second conductive connection bumps 160b of the first double-chip structure 100 as the lowermost chip may be prevented from being pressed.

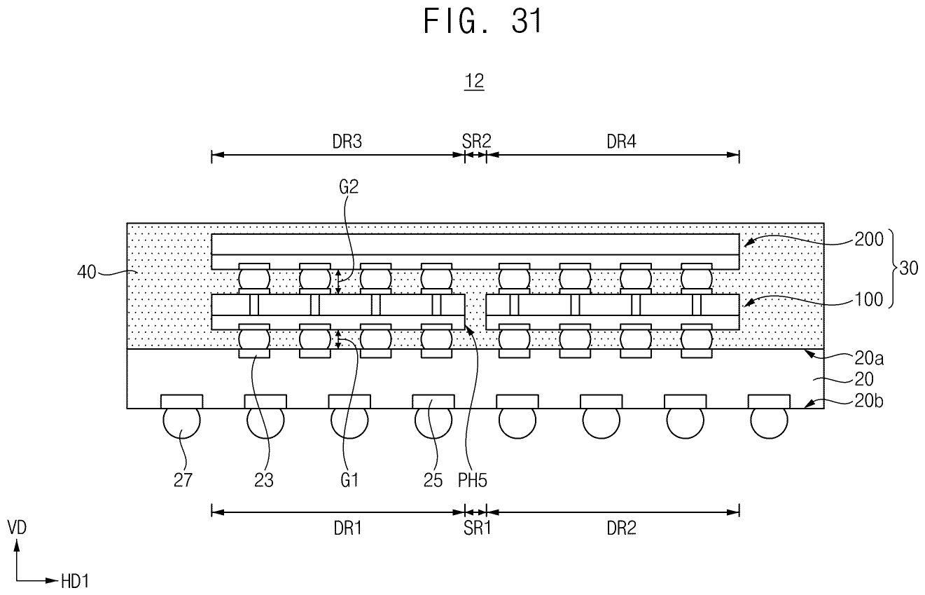

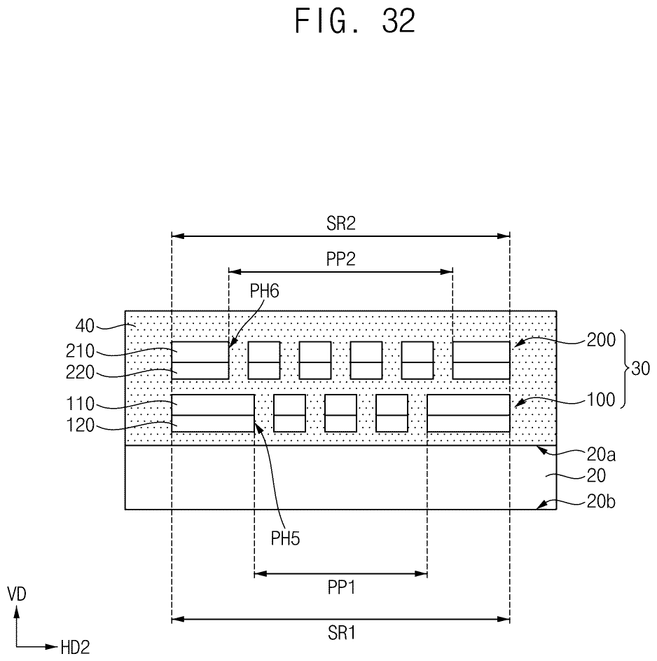

FIG. 31 is a cross-sectional view illustrating a semiconductor package in accordance to example embodiments. FIG. 32 is a cross-sectional view illustrating the semiconductor package of FIG. 31.

The semiconductor package illustrated in FIGS. 31 and 32 is substantially the same as the semiconductor package described with reference to FIGS. 1 to 7, except for arrangements of fifth through holes PH5 and sixth through holes PH6, so identical components are denoted by the same reference numerals, and repeated descriptions of identical components are omitted.

Referring to FIGS. 31 and 32, a semiconductor package 12 may include a substrate structure 20, a plurality of double-chip structures 30 sequentially mounted on the substrate structure 20, and a molding member 40 provided on the substrate structure 20 to cover the plurality of double-chip structures 30.

In example embodiments, the plurality of double-chip structures 30 may include a first double-chip structure 100 and a second double-chip structure 200 sequentially mounted on a chip mounting regions MR of the substrate structure 20.

In example embodiments, the first double-chip structure 100 may include a first semiconductor chip 100a, a second semiconductor chip 100b, and a first scribe lane region SR1 dividing the first semiconductor chip 100a and the second semiconductor chip 100b. For example, the first double-chip structure 100 may include a first semiconductor chip 100a disposed in a first die region DR1, the second semiconductor chip 100b disposed in a second die region DR2 spaced apart from the first die region DR1 in a first horizontal direction HD1, and a first connection portion 115 disposed in the first scribe lane region SR1 and connecting the first semiconductor chip 100a and the second semiconductor chip 100b.

The first double-chip structure 100 may include a first penetration portion PP1 disposed in the first scribe lane region SR1 to penetrate the first connection portion 115. For example, the first penetration portion PP1 may include a plurality of fifth through holes PH5.

In example embodiments, the second double-chip structure 200 may include a third semiconductor chip 200a, a fourth semiconductor chip 200b, and a second scribe lane region SR2 dividing the third semiconductor chip 200a and the fourth semiconductor chip 200b. For example, the second double-chip structure 200 may include the third semiconductor chip 200a disposed in a third die region DR3, a fourth semiconductor chip 200b disposed in a fourth die region DR4 spaced apart from the third die region DR3 in the first horizontal direction HD1, and a second connection portion 215 disposed in the second scribe lane region SR2 and connecting the third semiconductor chip 200a and the fourth semiconductor chip 200b.

The second double-chip structure 200 may include a second penetration portion PP2 disposed in the second scribe lane region SR2 to penetrate the second connection portion 215. For example, the second penetration portion PP2 may include a plurality of sixth through holes PH6.

Each of the plurality of fifth through holes PH5 and the plurality of sixth through holes PH6 may have a circular shape, when viewed in a plan view.

As illustrated in FIG. 32, the plurality of fifth through holes PH5 and the plurality of sixth through holes PH6 may be arranged alternately with each other, when viewed in a plan view. For example, the plurality of fifth through holes PH5 and the plurality of sixth through holes PH6 may be arranged respectively in the first and second scribe lane regions SR1 and SR2 such that the plurality of fifth through holes PH5 and the plurality of sixth through holes PH6 not overlap with each other along a vertical direction VD.

However, since this example embodiment is provided as an example, it will be understood that example embodiments are not limited thereto. Accordingly, the arrangements of the fifth through-hole and the sixth through-hole may be varied.

As mentioned above, the semiconductor package 12 may include the substrate structure 20, the first double-chip structure 100 and the second double-chip structure 200 sequentially mounted on the substrate structure 20, and the molding member 40 covering the first double-chip structure 100 and the second double-chip structure 200.

The first double-chip structure 100 may include the plurality of fifth through holes PH5 disposed in the first scribe lane region SR1, and the second double-chip structure 200 may include the plurality of sixth through holes PH6 disposed in the second scribe lane region SR2.

The plurality of fifth through holes PH5 and the plurality of sixth through holes PH6 may be arranged alternately with each other when viewed in a plan view, and the plurality of fifth through holes PH5 and the plurality of sixth through holes PH6 may not overlap with each other in the vertical direction.

Accordingly, the plurality of fifth through holes PH5 and the plurality of sixth through holes PH6 may change a flow path of a molding material while the molding material moves, thereby helping the molding member 40 to be sufficiently mixed during a process of filling a first gap G1 and a second gap G2. Additionally, the plurality of fifth through holes PH5 and the plurality of sixth through holes PH6 may provide various flow paths along which the molding material can move, thereby preventing the molding material from moving along a single path and becoming isolated in certain portions. Thus, the plurality of fifth through holes PH5 and the plurality of sixth through holes PH6 may prevent voids from occurring on a lower portion of the first double-chip structure 100 and a lower portion of the second double-chip structure 200.

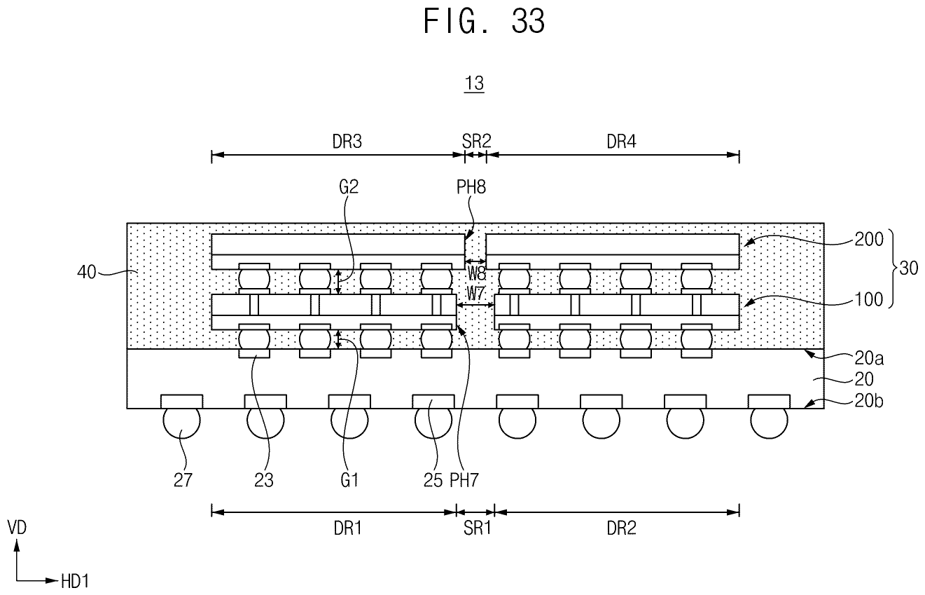

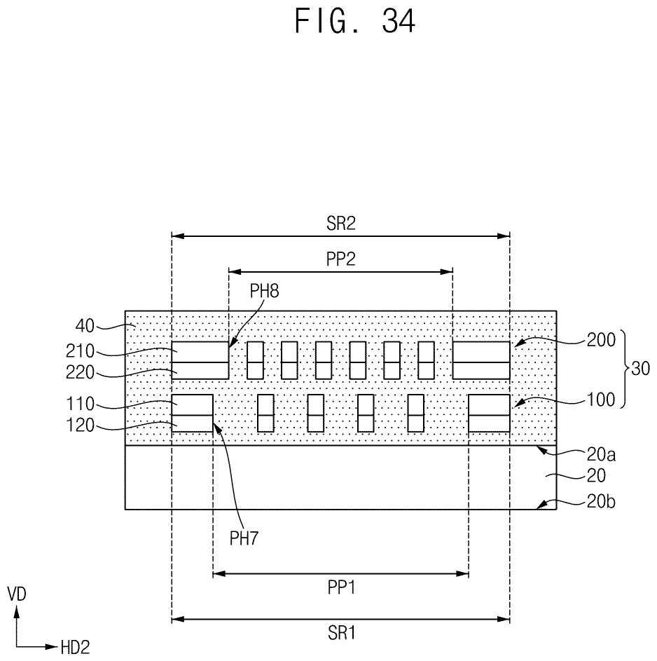

FIG. 33 is a cross-sectional view illustrating a semiconductor package in accordance with example embodiments. FIG. 34 is a cross-sectional view illustrating the semiconductor package of FIG. 33.

The semiconductor package illustrated in FIGS. 33 and 34 is substantially the same as the semiconductor package described with reference to FIGS. 1 to 7, except for seventh through holes PH7 and eighth through holes PH8, so identical components are denoted by the same reference numerals and repeated descriptions of identical components may be omitted.

Referring to FIGS. 33 and 34, a semiconductor package 13 may include a substrate structure 20, a plurality of double-chip structures 30 sequentially mounted on the substrate structure 20, and a molding member 40 provided on the substrate structure 20 and covering the plurality of double-chip structures 30.

In example embodiments, the plurality of double-chip structures 30 may include a first double-chip structure 100 and a second double-chip structure 200 sequentially mounted on a chip mounting regions MR of the substrate structure 20.

In example embodiments, the first double-chip structure 100 may include a first semiconductor chip 100a, a second semiconductor chip 100b, and a first scribe lane region SR1 dividing the first semiconductor chip 100a and the second semiconductor chip 100b. For example, the first double-chip structure 100 may include the first semiconductor chip 100a disposed in a first die region DR1, a second semiconductor chip 100b disposed in a second die region DR2 spaced apart from the first die region DR1 in a first horizontal direction HD1, and a first connection portion 115 disposed in the first scribe lane region SR1 and connecting the first semiconductor chip 100a and the second semiconductor chip 100b.

The first double-chip structure 100 may include a first penetration portion PP1 disposed in the first scribe lane region SR1 to penetrate the first connection portion 115. For example, the first penetration portion PP1 may include a plurality of seventh through holes PH7.

In example embodiments, the second double-chip structure 200 may include a third semiconductor chip 200a, a fourth semiconductor chip 200b, and a second scribe lane region SR2 dividing the third semiconductor chip 200a and the fourth semiconductor chip 200b. For example, the second double-chip structure 200 may include the third semiconductor chip 200a disposed in a third die region DR3, a fourth semiconductor chip 200b disposed in a fourth die region DR4 spaced apart from the third die region DR3 in the first horizontal direction HD1, and a second connection portion 215 disposed in the second scribe lane region SR2 and connecting the third semiconductor chip 200a and the fourth semiconductor chip 200b.

The second double-chip structure 200 may include a second penetration portion PP2 disposed in the second scribe lane region SR2 to penetrate the second connection portion 215. For example, the second penetration portion PP2 may include a plurality of eighth through holes PH8.

Each of the plurality of seventh through holes PH7 and the plurality of eighth through holes PH8 may have a circular shape, when viewed in a plan view.

Each of the plurality of seventh through holes PH7 may have a seventh diameter W7 along the horizontal direction, and each of the plurality of eighth through holes PH8 may have an eighth diameter W8 along the horizontal direction.

The seventh diameter W7 of each of the plurality of seventh through holes PH7 may be different from the eighth diameter W8 of each of the plurality of eighth through holes PH8. For example, the seventh diameter W7 of each of the plurality of seventh through holes PH7 may be greater than the eighth diameter W8 of each of the plurality of eighth through holes PH8.

The number of the plurality of seventh through holes PH7 may be different from the number of the plurality of eighth through holes PH8. For example, the number of the plurality of seventh through holes PH7 may be less than the number of the plurality of eighth through holes PH8.

Additionally, the plurality of seventh through holes PH7 and the plurality of eighth through holes PH8 may be aligned with each other in a vertical direction VD.

However, since this example embodiment is provided as a non-limiting example, it will be appreciated that embodiments of the present disclosure are not limited thereto. Accordingly, the arrangements and widths of the seventh through-hole PH7 and the eighth through-hole PH8 may be varied.

As mentioned above, the semiconductor package 13 may include the substrate structure 20, the first double-chip structure 100 and the second double-chip structure 200 sequentially mounted on the substrate structure 20, and the molding member 40 covering the first double-chip structure 100 and the second double-chip structure 200.

The first double-chip structure 100 may include the plurality of seventh through holes PH7 disposed in the first scribe lane region SR1, and the second double-chip structure 200 may include a plurality of eighth through holes PH8 disposed in the second scribe lane region SR2. The diameter W8 of each of the plurality of eighth through-hole may be less than the diameter W7 of each of the plurality of seventh through-hole. Further, the number of the plurality of eighth through holes may be greater than the number of the plurality of seventh through holes.

Accordingly, as an area of one through hole becomes narrower, the flow speed of the molding material moving through the through hole becomes faster. Therefore, the flow speed of the molding material passing through the eighth through-hole PH8 of the second double-chip structure 200 may be faster than the flow speed of the molding material passing through the seventh through-hole PH7 of the first double-chip structure 100. Thus, the eighth through-hole PH8 of the second double-chip structure 200 may relatively quickly move the molding material to a second gap G2, which is provided on lower portion of the second double-chip structure 200 that first contacts the molding material.

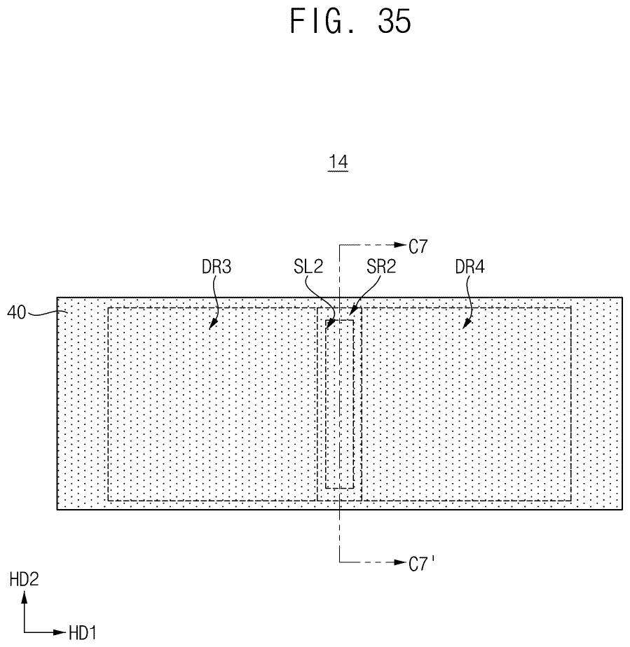

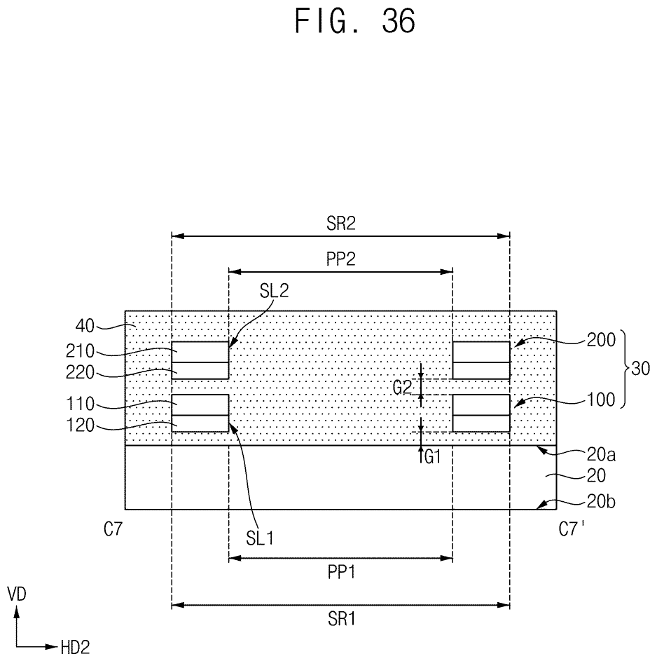

FIG. 35 is a plan view illustrating a semiconductor package in accordance with example embodiments. FIG. 36 is a cross-sectional view taken along a line C7-C7′ of FIG. 35.

The semiconductor package illustrated in FIGS. 35 and 36 is substantially the same as the semiconductor package described with reference to FIGS. 1 to 7, except for a first through slit SL1 and a second through slit SL2, so that identical components are denoted by the same reference numerals and repeated descriptions of identical components may be omitted.

Referring to FIGS. 35 and 36, a semiconductor package 14 may include a substrate structure 20, a plurality of double-chip structures 30 sequentially mounted on the substrate structure 20, and a molding member 40 provided on the substrate structure 20 to cover the plurality of double-chip structures 30.

In example embodiments, the plurality of double-chip structures 30 may include a first double-chip structure 100 and a second double-chip structure sequentially mounted on a chip mounting regions MR of the substrate structure 20.

In example embodiments, the first double-chip structure 100 may include a first semiconductor chip 100a, a second semiconductor chip 100b, and a first scribe lane region SR1 dividing the first semiconductor chip 100a and the second semiconductor chip 100b. For example, the first double-chip structure 100 may include the first semiconductor chip 100a disposed in a first die region DR1, the second semiconductor chip 100b in a second die region DR2 spaced apart from the first die region DR1 in a first horizontal direction HD, and a first connection portion 115 disposed in the first scribe lane region SR1 and connecting the first semiconductor chip 100a and the second semiconductor chip 100b.

The first double-chip structure 100 may include a first penetration portion PP1 disposed in the first scribe lane region SR1 to penetrate the first connection portion 115. For example, the first penetration portion PP1 may include a first through slit SL1.

In example embodiments, the second double-chip structure 200 may include a third semiconductor chip 200a, a fourth semiconductor chip 200b, and a second scribe lane region SR2 dividing the third semiconductor chip 200a and the fourth semiconductor chip 200b. For example, the second double-chip structure 200 may include the third semiconductor chip 200a disposed in a third die region DR3, a fourth semiconductor chip 200b in a fourth die region DR4 spaced apart from the third die region DR3 in the first horizontal direction HD1, and a second connection portion 215 disposed in the second scribe lane region SR2 and connecting the third semiconductor chip 200a and the fourth semiconductor chip 200b.

The second double-chip structure 200 may include a second penetration portion PP2 disposed in the second scribe lane region SR2 to penetrate the second connection portion 215. For example, the second penetration portion PP2 may include a second through slit SL2.

The first through slit SL1 and the second through slit SL2 may have a polygonal shape, when viewed in a plan view. For example, the first through slit SL1 and the second through slit SL2 may have a rectangular shape extending in the second horizontal direction HD2 when viewed in a plan view.

Each of the first through slit SL1 and the second through slit SL2 may at least partially overlap with each other when viewed in a plan view. Additionally, the first through slit SL1 and the second through slit SL2 may be aligned each other in a vertical direction VD.

Although the first double-chip structure 100 and the second double-chip structure 200 are illustrated as having through structures of the same shape, it will be appreciated that embodiments of the present disclosure are not limited thereto. For example, one from among the first double-chip structure 100 and the second double-chip structure 200 may have a plurality of through holes and the other may have a through slit.

Although only circular or rectangular through structures are illustrated in the figures, it will be appreciated that this is provided as a non-limiting example and embodiments of the present disclosure are not limited thereto. Accordingly, the shapes of the through structures may be varied.

As mentioned above, the semiconductor package 14 may include the substrate structure 20, the first double-chip structure 100 and the second double-chip structure 200 sequentially mounted on the substrate structure 20, and the molding member 40 covering the first double-chip structure 100 and the second double-chip structure 200.

The first double-chip structure 100 may have the first through slit SL1 disposed in the first scribe lane region SR1, and the second double-chip structure 200 may have the second through slit SL2 disposed in the second scribe lane region SR2. The first through slit SL1 and the second through slit SL2 may have a polygonal shape, when viewed in a plan view.

Accordingly, the first through slit SL1 and the second through slit SL2 may provide a relatively wide through hole area, and thus may effectively move the molding material. Therefore, the first through slit SL1 and the second through slit SL2 can help the molding member to quickly move to a central portion of the first double-chip structure and a central portion of the second double-chip structure, thereby reducing a flow speed difference of the molding member. Thus, voids may be prevented from occurring at a lower portion of the first double-chip structure 100 as a lowermost chip, thereby preventing first conductive connection bumps 160a and second conductive connection bumps 160b of the first double-chip structure 100 as the lowermost chip from being pressed.

The semiconductor package may include semiconductor devices such as logic devices or memory devices. The semiconductor package may include logic devices such as central processing units (CPUs), main processing units (MPUs), or application processors (APs), or the like, and volatile memory devices such as dynamic random access memory (DRAM) devices, high bandwidth memory (HBM) devices, or non-volatile memory devices such as flash memory devices, phase-change random access memory (PRAM) devices, magnetoresistive random access memory (MRAM) devices, resistive random access memory (ReRAM) devices, or the like.

According to some embodiments of the present disclosure, a method of manufacturing a semiconductor package may include: forming a first double-chip structure, the first double-chip structure including a first semiconductor chip, a second semiconductor chip, and a first scribe lane region dividing the first semiconductor chip and the second semiconductor chip, wherein the first double-chip structure further includes at least one first through hole in the first scribe lane region; forming a second double-chip structure, the second double-chip structure including a third semiconductor chip on the first semiconductor chip, a fourth semiconductor chip on the second semiconductor chip, and a second scribe lane region dividing the third semiconductor chip and the fourth semiconductor chip, wherein the second double-chip structure further includes a second through hole in the second scribe lane region; connecting the second double-chip structure to the first double-chip structure by a plurality of first conductive connection members between the first double-chip structure and the second double-chip structure, the plurality of first conductive connection members configured to electrically connect the first semiconductor chip and the third semiconductor chip and configured to electrically connect the second semiconductor chip and the fourth semiconductor chip; and providing a molding member on the first double-chip structure and the second double-chip structure and in the at least one first through hole and the at least one second through hole.

According to some embodiments of the present disclosure, the method may further include mounting the first double-chip structure and the second double-chip structure on a substrate structure, wherein the first double-chip structure is between the substrate structure and the second double-chip structure.

The foregoing is illustrative of example embodiments that do not limit the present disclosure. Although a few example embodiments have been described, those skilled in the art will readily appreciate that many modifications are possible in example embodiments without departing from the spirit and scope of the present disclosure. Accordingly, all such modifications are intended to be included within the scope of the present disclosure.

What is claimed is:

1. A semiconductor package, comprising:
a first double-chip structure comprising a first semiconductor chip, a second semiconductor chip, and a first scribe lane region dividing the first semiconductor chip and the second semiconductor chip, wherein the first double-chip structure further includes at least one first through hole in the first scribe lane region;
a second double-chip structure on the first double-chip structure, the second double-chip structure comprising a third semiconductor chip on the first semiconductor chip, a fourth semiconductor chip on the second semiconductor chip, and a second scribe lane region dividing the third semiconductor chip and the fourth semiconductor chip, wherein the second double-chip structure further includes at least one second through hole in the second scribe lane region;
a plurality of first conductive connection members between the first double-chip structure and the second double-chip structure, the plurality of first conductive connection members configured to electrically connect the first semiconductor chip and the third semiconductor chip and configured to electrically connect the second semiconductor chip and the fourth semiconductor chip; and
a molding member on the first double-chip structure and the second double-chip structure and in the at least one first through hole and the at least one second through hole.

2. The semiconductor package of claim 1, wherein, in a plan view of the semiconductor package, the at least one first through hole and the at least one second through hole overlap with each other.

3. The semiconductor package of claim 1, wherein, in a plan view of the semiconductor package, the at least one first through hole and the at least one second through hole are alternatively arranged with respect to each other.

4. The semiconductor package of claim 1, wherein each of the at least one first through hole comprises a first diameter, and each of the at least one second through hole comprises a second diameter that is equal to the first diameter.

5. The semiconductor package of claim 1, wherein each of the at least one first through hole comprises a first diameter, and each of the at least one second through hole comprises a second diameter that is different from the first diameter.

6. The semiconductor package of claim 1, further comprising:
a substrate structure comprising a mounting region,
wherein the first double-chip structure and the second double-chip structure are on the mounting region, the first double-chip structure being between the mounting region and the second double-chip structure.

7. The semiconductor package of claim 6, wherein a first diameter of each of the at least one first through hole becomes narrower towards the substrate structure, and a second diameter of each of the at least one second through hole becomes narrower towards the substrate structure.

8. The semiconductor package of claim 6, wherein the first double-chip structure further comprises:
a first through via in the first semiconductor chip, wherein the first through via is configured to electrically connect the substrate structure and the third semiconductor chip; and
a second through via in the second semiconductor chip, wherein the second through via is configured to electrically connect the substrate structure and the fourth semiconductor chip.

9. The semiconductor package of claim 6, further comprising:
a second conductive connection member between the substrate structure and the first double-chip structure, wherein the second conductive connection member is configured to electrically connect the substrate structure and the first double-chip structure.

10. The semiconductor package of claim 9, wherein the molding member is in a first gap between the substrate structure and the first double-chip structure, and in a second gap between the first double-chip structure and the second double-chip structure.

11. A semiconductor package, comprising:
a substrate structure comprising a mounting region;
a first double-chip structure on the mounting region of the substrate structure, the first double-chip structure comprising:
a pair of first semiconductor chips arranged along a first horizontal direction;
a first scribe lane region dividing the pair of first semiconductor chips; and
a first penetration portion penetrating the first scribe lane region;
a second double-chip structure on the first double-chip structure, the second double-chip structure comprising:
a pair of second semiconductor chips arranged along the first horizontal direction;
a second scribe lane region dividing the pair of second semiconductor chips; and
a second penetration portion penetrating the second scribe lane region;
at least one first conductive connection member between the substrate structure and the first double-chip structure, wherein the at least one first conductive connection member is configured to electrically connect the substrate structure and the first double-chip structure;
at least one second conductive connection member between the first double-chip structure and the second double-chip structure, wherein the at least one second conductive connection member is configured to electrically connect the first double-chip structure and the second double-chip structure; and
a molding member on the substrate structure, the first double-chip structure, and the second double-chip structure, wherein the molding member is in the first penetration portion and the second penetration portion.

12. The semiconductor package of claim 11, wherein the first double-chip structure is connected to the substrate structure by the at least one first conductive connection member, and a first gap is between the substrate structure and the first double-chip structure, and
wherein a portion of the molding member is within the first gap, the portion on the at least one first conductive connection member.

13. The semiconductor package of claim 11, wherein the second double-chip structure is connected to the first double-chip structure by the at least one second conductive connection member, and a second gap is between the first double-chip structure and the second double-chip structure, and
wherein a portion of the molding member is within the second gap, the portion on the at least one second conductive connection member.

14. The semiconductor package of claim 11, wherein the pair of first semiconductor chips comprises a first-first semiconductor chip and a first-second semiconductor chip, and
wherein the pair of second semiconductor chips comprises:
a second-first semiconductor chip on the first-first semiconductor chip; and
a second-second semiconductor chip on the first-second semiconductor chip.

15. The semiconductor package of claim 14, wherein the first double-chip structure further comprises:
at least one first through via in the first-first semiconductor chip, the at least one first through via configured to electrically connect the substrate structure and the second-first semiconductor chip; and
at least one second through via in the first-second semiconductor chip, the at least one second through via configured to electrically connect the substrate structure and the second-second semiconductor chip.

16. The semiconductor package of claim 11, wherein the first penetration portion includes a plurality of first through holes arranged along a second horizontal direction perpendicular to the first horizontal direction, and
wherein the second penetration portion includes a plurality of second through holes arranged along the second horizontal direction.

17. The semiconductor package of claim 16, wherein, in a plan view of the semiconductor package, the plurality of first through holes and the plurality of second through holes overlap with each other.

18. The semiconductor package of claim 16, wherein, in a plan view of the semiconductor package, the plurality of first through holes and the plurality of second through holes are alternatively arranged with respect to each other.

19. The semiconductor package of claim 11, wherein at least one from among the first penetration portion and the second penetration portion includes a through slit,
wherein, in a plan view of the semiconductor package, the through slit comprises a polygonal shape, and
wherein the through slit extends in a second horizontal direction perpendicular to the first horizontal direction.

20. A semiconductor package, comprising:
a substrate structure comprising a mounting region;
a first double-chip structure on the mounting region of the substrate structure, the first double-chip structure comprising a first semiconductor chip, a second semiconductor chip, and a first scribe lane region dividing the first semiconductor chip and the second semiconductor chip;
a second double-chip structure on the first double-chip structure, the second double-chip structure comprising a third semiconductor chip on the first semiconductor chip, a fourth semiconductor chip on the second semiconductor chip, and a second scribe lane region dividing the third semiconductor chip and the fourth semiconductor chip;
at least one first conductive connection member between the substrate structure and the first double-chip structure, wherein a first gap is between the substrate structure and the first double-chip structure, and the at least one first conductive connection member is configured to electrically connect the substrate structure and the first double-chip structure;
at least one second conductive connection member between the first double-chip structure and the second double-chip structure, wherein a second gap is between the first double-chip structure and the second double-chip structure, and the at least one second conductive connection member is configured to electrically connect the first double-chip structure and the second double-chip structure; and
a molding member on the substrate structure, the first double-chip structure, and the second double-chip structure,
wherein the first double-chip structure further includes at least one first through hole in the first scribe lane region,
wherein the second double-chip structure further includes at least one second through hole in the second scribe lane region, and
wherein the molding member is in the first gap, the second gap, the at least one first through hole, and the at least one second through hole.
